(19) United States
(12) Patent Application Publication
(10) Pub. No.: US 2025/0140767 A1
(43) Pub. Date: May 1, 2025

(54) DISPLAY DEVICE

(71) Applicant: Samsung Display Co., Ltd., Yongin-si (KR)

(72) Inventors: SANGHO PARK, Yongin-si (KR); KIBUM KIM, Yongin-si (KR); SOOCHUL KIM, Yongin-si (KR); TAEGYUN KIM, Yongin-si (KR); CHUL JONG YOO, Yongin-si (KR)

(73) Assignee: Samsung Display Co., Ltd., Yongin-si (KR)

(21) Appl. No.: 18/931,569

(22) Filed: Oct. 30, 2024

(30) Foreign Application Priority Data
Oct. 31, 2023 (KR) 10-2023-0147888

(51) Int. Cl. H01L 25/16; H01L 27/15; H01L 33/14; H01L 33/24; H01L 33/30; H01L 33/38; H01L 33/40; H01L 33/42; H01L 33/60; H01L 33/62

(52) U.S. Cl. CPC H01L 25/167; H10H 20/816; H10H 20/821; H10H 20/831; H10H 20/833; H10H 20/835; H10H 20/856; H10H 20/857; H10H 29/142; H10H 20/032; H10H 20/824

(57) ABSTRACT

Provided is a display device including a CMOS wafer and a light emitting diode disposed on a first area of the CMOS wafer. The light emitting diode includes a first electrode member, an emission layer disposed on the first electrode member, and a second electrode member disposed on a semiconductor junction member. The first electrode member includes a metal layer, a reflective layer disposed on the metal layer, and a first transparent conductive layer disposed on the reflective layer.

### CROSS-REFERENCE TO RELATED APPLICATION(S)

This application claims priority to and benefits of Korean Patent Application No. 10-2023-0147888 under 35 U.S.C. § 119, filed on Oct. 31, 2023, the entire contents of which are incorporated herein by reference.

### BACKGROUND

### 1. Technical Field

Embodiments relate to a display device, and more particularly, to a display device including a semiconductor wafer and a light emitting diode.

### 2. Description of the Related Art

Electronic equipment for providing an image to a user such as smartphones, digital cameras, laptop computers, navigations, and smart televisions includes a display device for displaying an image. Augmented reality devices, virtual reality devices, and video projection devices may include micro display devices. Such a micro display device may include a semiconductor wafer and a light emitting diode disposed on the semiconductor wafer to display a high-brightness image while being driven at low power.

### SUMMARY

Embodiments provide a display device capable of reducing or minimizing light loss and defects.

However, embodiments are not limited to those set forth herein. The above and other embodiments will become more apparent to one of ordinary skill in the art to which the disclosure pertains by referencing the detailed description of the disclosure given below.

An embodiment provides a display device including a complementary metal oxide semiconductor (CMOS) wafer and a plurality of light emitting diodes disposed on the CMOS wafer and disposed in a first area of the CMOS wafer in a plan view. Each of the light emitting diodes may include a first electrode member, an emission layer disposed on the first electrode member, and a second electrode member disposed on the emission layer. The first electrode member may include a metal layer, a reflective layer disposed on the metal layer, and a first transparent conductive layer disposed on the reflective layer.

The metal layer may include at least one of gold (Au), copper (Cu), silver (Ag), tin (SN), titanium (Ti), zirconium (Zr), and tantalum (Ta), or may include an alloy of at least two metals of gold (Au), copper (Cu), silver (Ag), tin (SN), titanium (Ti), zirconium (Zr), and tantalum (Ta).

The metal layer may include a first metal layer and a second metal layer disposed on the first metal layer, the first metal layer may include at least one of gold (Au), copper (Cu), silver (Ag), tin (SN), titanium (Ti), zirconium (Zr), and tantalum (Ta), and the second metal layer may include another one of gold (Au), copper (Cu), silver (Ag), tin (SN), titanium (Ti), zirconium (Zr), and tantalum (Ta).

The metal layer further may include a third metal layer disposed on the second metal layer, the third metal layer may include at least one of gold (Au), copper (Cu), silver (Ag), tin (SN), titanium (Ti), zirconium (Zr), and tantalum (Ta), and the third metal layer may include a metal different from the second metal layer.

The first electrode member further may include: a first barrier layer disposed between the metal layer and the reflective layer; and a second barrier layer disposed between the reflective layer and the first transparent conductive oxide layer, and each of the first barrier layer and the second barrier layer may include a nitride layer made of barrier metal nitride.

The first barrier layer further may include a barrier metal layer disposed at at least one side of upper and lower sides of the nitride layer made of the barrier metal nitride, and the barrier metal layer may include titanium (Ti) or tantalum (Ta).

The first electrode member further may include a barrier layer disposed below the metal layer, and the barrier layer may include titanium nitride or tantalum nitride.

The CMOS wafer may include: a silicon substrate in which a source region or a drain region is formed; a gate electrode disposed on the silicon substrate; a first insulating layer covering the gate electrode and disposed on the silicon substrate; a first contact electrode electrically connected to the source region or the drain region through a first contact hole passing through the first insulating layer; a second insulating layer covering the first contact electrode and disposed on the first insulating layer; and a second contact electrode electrically connected to the first contact electrode through a second contact hole passing through the second insulating layer and electrically connected to the metal layer of the first electrode member.

The second contact electrode may include: a metal member disposed inside the second contact hole; and a barrier layer disposed between a side surface of the metal member and an inner surface of the second contact hole and disposed between a lower surface of the metal member and an upper surface of the first contact electrode exposed through the second contact hole, and the barrier layer may include a metal layer made of barrier metal and a nitride layer made of barrier metal nitride.

An upper surface of the second contact electrode may be concave.

The second electrode member may include a second transparent conductive oxide layer.

The second electrode member may be a cathode of each of the plurality of light emitting diodes, and the second electrode member further may include an electrode metal layer disposed between the second transparent conductive oxide layer and a semiconductor junction member.

The second electrode member may be an anode of each of the plurality of light emitting diodes, the first electrode member may be a cathode of each of the plurality of light emitting diodes, the emission layer may include: an n-type semiconductor layer; an active layer disposed on the n-type semiconductor layer; and a p-type semiconductor layer disposed on the active layer, the n-type semiconductor layer may include a first portion and a second portion having a width less than that of the first portion in cross section, and a side surface of the second portion is an inclined surface that is inclined with respect to the first electrode member.

In a plan view, the emission layer may be disposed inside the first electrode member.

The display device may further include: a first side insulating layer disposed on a side surface of the first electrode member, a side surface of the emission layer, a side surface of the second electrode member, and an upper surface of the second electrode member; and a side reflective layer disposed outside the first side insulating layer.

The side reflective layer may be adjacent to at least one of the side surface of the first electrode member, the side surface of the emission layer, and the side surface of the second electrode member.

The display device may further include: a second side insulating layer, wherein a partial area of an upper surface of the first electrode member may be exposed from the emission layer, the second side insulating layer is disposed inside the first side insulating layer and corresponds to an upper surface of the first electrode member, the side surface of the emission layer, the side surface of the second electrode member, and an upper surface of the second electrode member, and an opening through which the partial area of the upper surface of the second electrode member is exposed is formed in the side reflective layer, the first side insulating layer, and the second side insulating layer.

The display device may further include: a common electrode, wherein the plurality of light emitting diodes may include a first light emitting diode and a second light emitting diode, the common electrode may electrically connect the second electrode member of the first light emitting diode to the second electrode member of the second light emitting diode, and the common electrode may adhere to the partial area of the upper surface of the second electrode member through the opening.

The display device may further include: a planarization layer disposed on the CMOS wafer and adjacent to a side surface of the first electrode member and a side surface of the emission layer; and a common electrode disposed on the planarization layer and electrically connected to the second electrode member of each of the plurality of light emitting diodes, wherein the first area of the CMOS wafer may include a plurality of unit areas, on which the plurality of light emitting diodes are disposed, and a boundary area between the plurality of unit areas, and the planarization layer may overlap the plurality of unit areas and the boundary area.

The display device may further include: an auxiliary electrode, wherein a plurality of first trenches overlapping the boundary area and extending in a first direction and a plurality of second trenches overlapping the boundary area and extending in a second direction intersecting the first direction may be formed in the planarization layer, and the auxiliary electrode may be disposed inside the plurality of first trenches and the plurality of second trenches and electrically connected to the common electrode.

The auxiliary electrode may include: a metal member disposed inside the plurality of first trenches and the plurality of second trenches; and a barrier layer disposed between the metal member and the plurality of first and second trenches.

The display device may further include: a plurality of dummy light emitting diodes disposed in a second area outside the first area of the CMOS wafer in a plan view, wherein the plurality of dummy light emitting diodes may not emit light.

The display device may further include: a common electrode overlapping the first area and the second area and electrically connected to the second electrode member of each of the plurality of light emitting diodes, wherein the common electrode may not be electrically connected to the plurality of dummy light emitting diodes.

The plurality of dummy light emitting diodes may have a same laminated structure as the plurality of light emitting diodes.

The display device may further include: a common electrode overlapping the first area and the second area and electrically connected to the second electrode member of each of the plurality of light emitting diodes; a voltage transmission electrode extending from the common electrode to a third area outside the second area of the CMOS wafer; and a pad electrode electrically connected to the voltage transmission electrode on the third area.

The display device may further include: a passivation layer overlapping the first area, the second area, and the third area, covering the common electrode and the voltage transmission electrode, and having an opening through which a connection area of the voltage transmission electrode is exposed, wherein the pad electrode may be electrically connected to the connection area of the voltage transmission electrode through the opening of the passivation layer.

The display device may further include: a common line disposed below the voltage transmission electrode and electrically connected to the voltage transmission electrode.

The common line may include a first conductive member having a same laminated structure as the first electrode member.

The common line may include: an insulating member disposed on an upper surface of the first conductive member; and a second conductive member disposed on at least the first conductive member and electrically connected to the first conductive member.

The display device may further include: a planarization layer which is disposed between the common line and the voltage transmission electrode and in which a plurality of trenches are formed; and an auxiliary electrode disposed in the plurality of trenches and electrically connected the common line to the voltage transmission electrode.

The auxiliary electrode may extend from one area of each of the plurality of trenches and may be electrically connected to the common line through through-holes passing through the planarization layer.

The third area of the CMOS wafer may include an inner area on which the common electrode is disposed and an outer area on which the common electrode is not disposed, and the auxiliary electrode may electrically connect the common electrode to the common line on the inner area.

The display device may further include: a common electrode electrically connected to the second electrode member of each of the plurality of light emitting diodes to overlap the first area; a pad electrode disposed on an outer area of the first area to receive a power voltage; an auxiliary electrode including a first portion disposed below the common electrode and electrically connected to the common electrode and a second portion spaced apart from the first portion, disposed below the pad electrode, and electrically connected to the pad electrode; and a common line including a first common portion disposed below the first portion of the auxiliary electrode and electrically connected to the first portion of the auxiliary electrode and a second common portion disposed below the second portion of the auxiliary electrode and electrically connected to the second portion of the auxiliary electrode, wherein the CMOS wafer may include a connection electrode electrically connected to each of the first common portion of the common line and the second portion of the common line.

The CMOS wafer may include: a silicon substrate in which a source region or a drain region is formed; a gate electrode disposed on the silicon substrate; a first insulating layer covering the gate electrode and disposed on the silicon substrate; a first contact electrode electrically connected to the source region or a drain region through a first contact hole formed in the first insulating layer; a second insulating layer covering the first contact electrode and disposed on the first insulating layer; and a second contact electrode electrically connected to the first contact electrode through a second contact hole passing through the second insulating layer and electrically connected to the metal layer of the first electrode member, wherein the connection electrode and the first contact electrode may be disposed on a same layer.

The display device may further include: a plurality of lenses disposed on the plurality of light emitting diodes to respectively correspond to the plurality of light emitting diodes.

### BRIEF DESCRIPTION OF THE DRAWINGS

The accompanying drawings are included to provide a further understanding of the disclosure, and are incorporated in and constitute a part of this specification. The drawings illustrate embodiments and, together with the description, serve to explain principles of the disclosure. In the drawings:

FIG. 1 is a schematic perspective view of a display device according to an embodiment;

FIG. 2 is a schematic cross-sectional view illustrating an example of the display device illustrated in FIG. 1;

FIG. 3A is a schematic plan view illustrating a state in which a common electrode is disposed on a display area and a non-display area of the display device according to an embodiment;

FIG. 3B is a schematic plan view illustrating an arrangement relationship between the common electrode, a voltage transmission electrode, and auxiliary electrodes according to an embodiment;

FIG. 4A is an enlarged schematic plan view illustrating a partial area of a first area of FIG. 3A;

FIG. 4B is a schematic cross-sectional view taken along lie I-I′ of FIG. 4A;

FIG. 4C is an enlarged cross-sectional view of an area B1 of FIG. 4B illustrating a contact area between a second contact electrode and a first electrode member;

FIG. 4D is an enlarged schematic cross-sectional view of an area B2 of FIG. 4B illustrating a contact area between a passivation layer and a lens;

FIGS. 4E to 4F are schematic cross-sectional views illustrating the first electrode member of FIG. 4B;

FIG. 4G is a schematic cross-sectional view illustrating a light emitting diode of FIG. 4B;

FIG. 5A is an enlarged schematic plan view illustrating a partial area of a second area of FIG. 3A;

FIG. 5B is a schematic cross-sectional view taken along line II-II′ of FIG. 5A.

FIG. 6A is an enlarged schematic plan view illustrating a partial area of a third-1 area of FIG. 3A;

FIG. 6B is a schematic cross-sectional view taken along line III-III′ of FIG. 6A;

FIG. 7A is an enlarged schematic plan view illustrating a partial area of a third-2 area of FIG. 3A;

FIG. 7B is a schematic cross-sectional view taken along line IV-IV′ of FIG. 7A;

FIG. 8A is a schematic cross-sectional view corresponding to a second area according to an embodiment;

FIG. 8B is a schematic cross-sectional view corresponding to a third-2 area according to an embodiment;

FIGS. 9A to 9S are schematic cross-sectional views illustrating a process of manufacturing a display device according to an embodiment;

FIG. 10A is a schematic plan view illustrating an arrangement relationship between a common electrode, a voltage transmission electrode, and an auxiliary electrode according to an embodiment;

FIG. 10B is an enlarged schematic plan view illustrating a partial area of the third-2 area according to an embodiment;

FIGS. 10C and 10D are schematic cross-sectional views taken along line V-V′ of FIG. 10B;

FIG. 10E is an enlarged schematic plan view illustrating a partial area of the third-2 area according to an embodiment;

FIG. 10F is a schematic plan view illustrating an arrangement relationship between a common electrode, a voltage transmission electrode, and an auxiliary electrode according to an embodiment;

FIG. 11A is a schematic cross-sectional view illustrating a display device according to an embodiment;

FIG. 11B is a schematic cross-sectional view illustrating a light emitting diode according to an embodiment; and

FIG. 11C is a schematic cross-sectional view illustrating a first electrode member according to an embodiment.

### DETAILED DESCRIPTION OF THE EMBODIMENTS

In the following description, for the purposes of explanation, numerous specific details are set forth in order to provide a thorough understanding of various embodiments or implementations of the invention. As used herein, “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the scope of the invention.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element or a layer is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the axis of the first direction DR1, the axis of the second direction DR2, and the axis of the third direction DR3 are not limited to three axes of a rectangular coordinate system, such as the X, Y, and Z—axes, and may be interpreted in a broader sense. For example, the axis of the first direction DR1, the axis of the second direction DR2, and the axis of the third direction DR3 may be perpendicular to one another, or may represent different directions that are not perpendicular to one another. For the purposes of this disclosure, “at least one of A and B” may be understood to mean A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one element's relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein should be interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

Hereinafter, embodiments will be described with reference to the accompanying drawings.

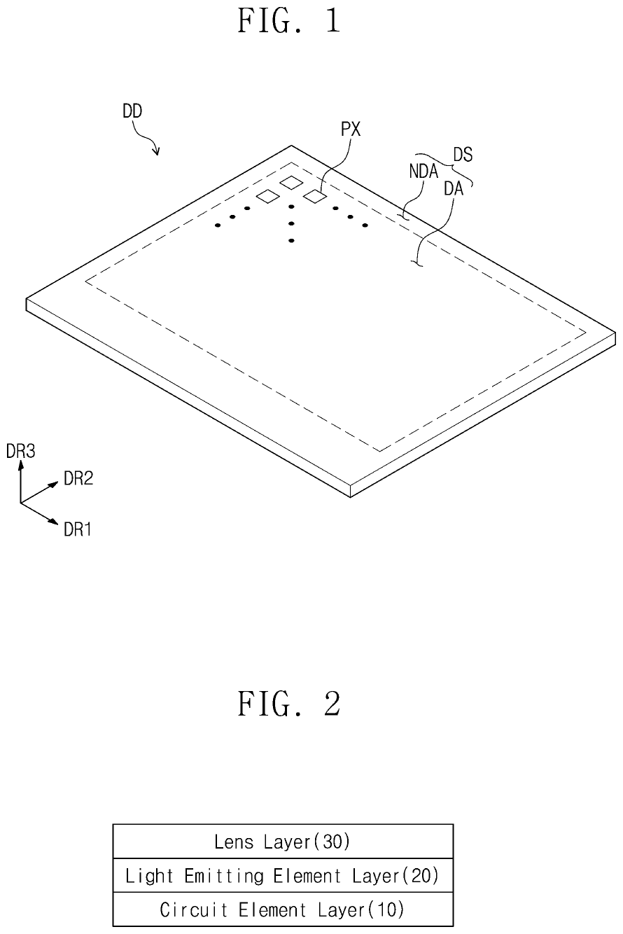

FIG. 1 is a schematic perspective view of a display device DD according to an embodiment.

Referring to FIG. 1, the display device DD according to an embodiment may have a rectangular shape having long sides extending in a first direction DR1 and short sides extending in a second direction DR2 intersecting the first direction DR1. However, embodiments are not limited thereto. For example, the display device DD may have various shapes such as a circular shape or a polygonal shape. Hereinafter, a direction that substantially perpendicularly crosses a plane defined by the first direction DR1 and the second direction DR2 is defined as a third direction DR3. In the description, the meaning when viewed on a plane is defined as a state viewed in the third direction DR3.

A top surface (or upper surface) of the display device DD may be defined as a display surface DS and have a plane defined by the first direction DR1 and the second direction DR2. Images generated in the display device DD may be provided to a user through the display surface DS.

The display surface DS may include a display area DA and a non-display area NDA around the display area DA. The display area DA may display an image, and the non-display area NDA may not display an image. The non-display area NDA may surround the display area DA, and the non-display area NDA may be disposed at a side of the display area DA. However, embodiments are not limited thereto.

Pixels PX may be disposed on the display area DA. The pixels PX may be disposed in the form of a matrix. Each of the pixels PX may include a pixel circuit and a light emitting diode. All of the pixels PX may generate light having the same color. In an embodiment, the pixels PX may include a plurality of groups that generate light having different colors.

FIG. 2 is a schematic cross-sectional view illustrating an example of the display device DD illustrated in FIG. 1.

Referring to FIG. 2, the display device DD may include a circuit element layer 10, a light emitting element layer 20, and a lens layer 30. However, embodiments are not limited thereto, and in an embodiment, the lens layer 30 may be omitted, and another functional layer may be added.

The circuit element layer 10 may include a pixel circuit. The pixel circuit may control an operation of the light emitting diode of the light emitting element layer 20, which will be described later. The pixel circuit may include at least one transistor. The circuit element layer 10 may include a CMOS wafer. The CMOS wafer may include a complementary nMOSFET (NMOS) and a pMOSFET (PMOS). Pixel areas may be regularly arranged on the CMOS wafer, and the pixel circuit may be disposed on each pixel area.

The light emitting element layer 20 may include the light emitting diode electrically connected to the pixel circuit. The light emitting diode may be a type of compound semiconductor and may be an electrically driven light emitting diode including gallium (Ga), phosphorus (P), and arsenic (As) as main semiconductor materials. In case that forward current is applied to a p-n junction structure, electrons and holes may be combined at a junction surface to generate light having a specific wavelength corresponding to band gap energy.

The lens layer 30 may be disposed on the light emitting element layer 20 and may include a lens. The lens may be disposed to correspond to (or overlap) the light emitting diode. The lens condenses the light emitted from the light emitting diode. The light condensed through the lens may be transmitted through a light guide unit.

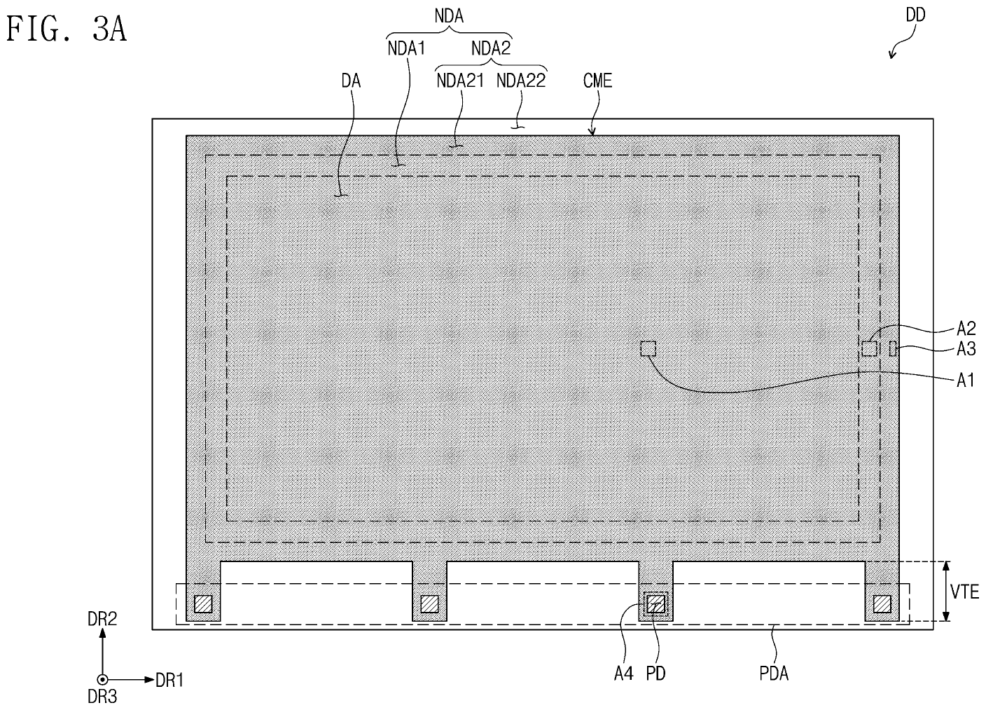

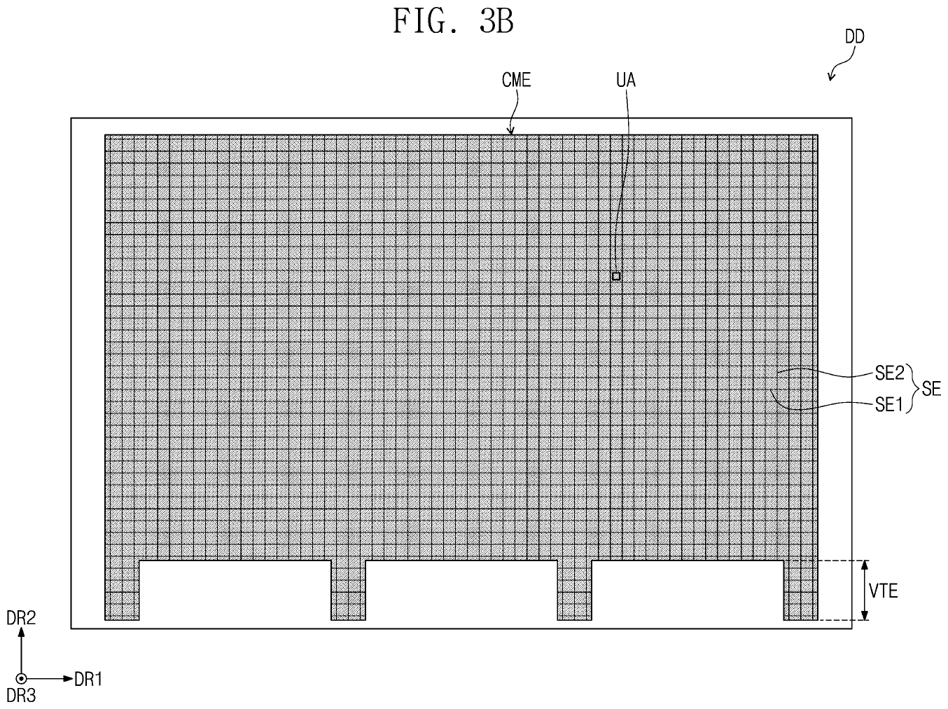

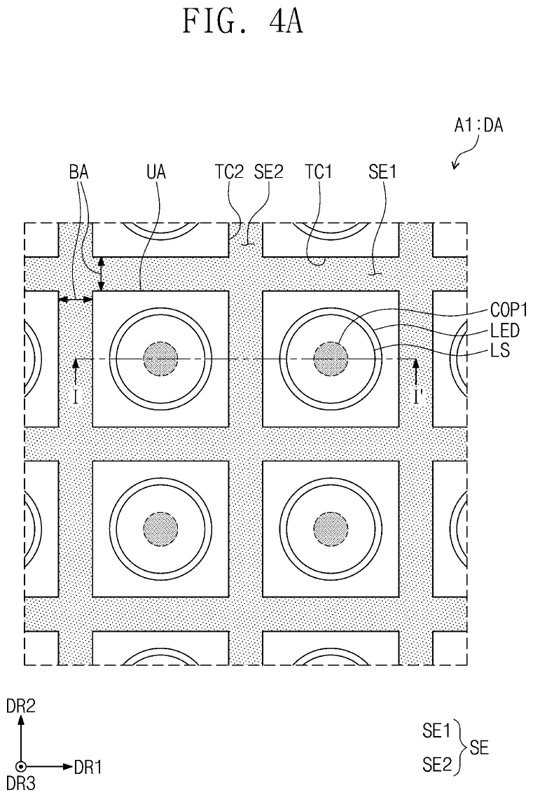

FIG. 3A is a schematic plan view illustrating a state in which a common electrode CME is disposed on a display area DA and a non-display area NDA of the display device DD according to an embodiment. The display area DA and the non-display area NDA of the display device DD may be applied to the circuit element layer 10 described in FIG. 2, e.g., to the CMOS wafer. Hereinafter, the circuit element layer 10 will be described as the CMOS wafer 10 and will be referred to as the same symbol.

The common electrode CME may cover at least the display area DA. The common electrode CME may transmit a power voltage applied from the outside to the entire display area DA. Hereinafter, the display area DA will be described as the first area DA and will be referred to as the same symbol.

The non-display area NDA may be divided into a plurality of areas. In an embodiment, the non-display area NDA may include a second area NDA1 and a third area NDA2.

The second area NDA1 may be disposed outside the first area DA and may be an area on which dummy light emitting diodes, which will be described later, are disposed. In an embodiment, the second area NDA1 may surround the first area DA, but embodiments are not necessarily limited thereto. The dummy light emitting diodes may have the same laminated structure as the light emitting diodes of the first area DA, but may not be electrically connected to the common electrode CME and thus may not be driven (or may emit light). Structural features of the dummy light emitting diodes will be described later.

In case of forming light emitting diodes by the same process on a specific area, an outer area may have different process conditions compared to an inner area. For example, a thickness of a deposited metal layer may be small, or an etch rate may be different. Thus, defective light emitting diodes may be provided on the outer area. In consideration of this structure, the light emitting diodes disposed at the outside may not be used as effective light emitting diodes, but be used as the dummy light emitting diodes. In case that the process conditions and process efficiency are consistent regardless of the areas, the dummy light emitting diodes may be omitted, and thus, the second area NDA1 may be omitted in an embodiment.

The third area NDA2 may include an inner area NDA21 (hereinafter, referred to as a third-1 area) and an outer area NDA22 (hereinafter, referred to as a third-2 area) divided according to the arrangement of the common electrode CME. The third-1 area NDA21 may be disposed closer to the first area DA than the third-2 area NDA22.

The common electrode CME may be disposed on the third-1 area NDA21, but the light emitting diode or the dummy light emitting diode may not be disposed. In an embodiment, the third-1 area NDA21 may surround the second area NDA1, but embodiments are not necessarily limited thereto. A range of the third-1 area NDA21 may be determined by an edge portion of the common electrode CME.

The third-2 area NDA22 may be an area on which the common electrode CME is not disposed. In an embodiment, the third-2 area NDA22 may surround the third-1 area NDA21, but embodiments are not limited thereto. Driving circuits may be disposed on the third-2 area NDA22 of the CMOS wafer 10 (see FIG. 2). For example, scan drivers may be disposed on left and right areas of the third-2 area NDA22, respectively, with the first area DA therebetween. A data driver may be disposed on a partial area of the third-2 area NDA22 disposed below the first area DA. For example, an analog circuit such as a power circuit may be disposed on a portion of the third-2 area NDA22. The scan driver, the data driver, and the analog circuitry described above may be embedded in the CMOS wafer. For example, the scan driver, the data driver, and the analog circuit may include transistors formed in the same manner as the pixel circuit.

A pad area PDA in which pad electrodes PD are disposed may be disposed at a side of the third-2 area NDA22. The pad area PDA may correspond to a partial area of the third-2 area NDA22. A circuit board may be connected to the pad area PDA. Although only four pad electrodes PD that receive the power voltage applied to the common electrode CME are illustrated in FIG. 3A, more pad electrodes may be disposed on the pad area PDA. The pad electrodes may receive data image signals or control signals from the outside to provide the signals to the data driver.

Referring to FIG. 3A, a voltage transmission electrode VTE may be disposed on the third-2 area NDA22. Four voltage transmission electrodes VTE corresponding to the four pad electrodes PD are illustrated. The voltage transmission electrode VTE may extend from the common electrode CME toward the pad area PDA. The voltage transmission electrode VTE may be formed by the same process, by which the common electrode CME is formed, may have the same laminated structure, and may have an integrated shape. The voltage transmission electrode VTE and the common electrode CME may be different portions of one electrode formed by the same process.

FIG. 3B is a schematic plan view illustrating an arrangement relationship between the common electrode CME, the voltage transmission electrode VTE, and an auxiliary electrode SE according to an embodiment.

The auxiliary electrode SE may overlap the common electrode CME and the voltage transmission electrode VTE. In the third direction DR3, the auxiliary electrode SE may be disposed below the common electrode CME and the voltage transmission electrode VTE.

The auxiliary electrode SE may include first auxiliary electrodes SE1 extending in the first direction DR1 and second auxiliary electrodes SE2 extending in the second direction DR2. The first auxiliary electrodes SE1 may be arranged in the second direction DR2, and the second auxiliary electrodes SE2 may be arranged in the first direction DR1.

A unit area UA in an area defined by two most adjacent first auxiliary electrodes SE1 of the first auxiliary electrodes SE1 and two most adjacent second auxiliary electrodes SE2 of the second auxiliary electrodes SE2 may be disposed. However, the unit area UA may be disposed in the display area DA of FIG. 3A. In FIG. 3B, a unit area UA is representatively illustrated. At least the light emitting diode may be disposed on the unit area UA. This will be described later in detail.

A portion of the auxiliary electrode SE may overlap the common electrode CME, and the portion overlapping the common electrode CME may be entirely connected to the common electrode CME to reduce a voltage drop occurring in the common electrode CME. The other portion of the auxiliary electrode SE may overlap the voltage transmission electrode VTE, and the portion overlapping with the voltage transmission electrode VTE may be entirely connected to the voltage transmission electrode VTE to reduce resistance in a voltage transmission path between the pad electrode PD (see FIG. 3A) and the common electrode CME. The auxiliary electrode SE may be formed by the same process regardless of the areas and may have an integrated shape.

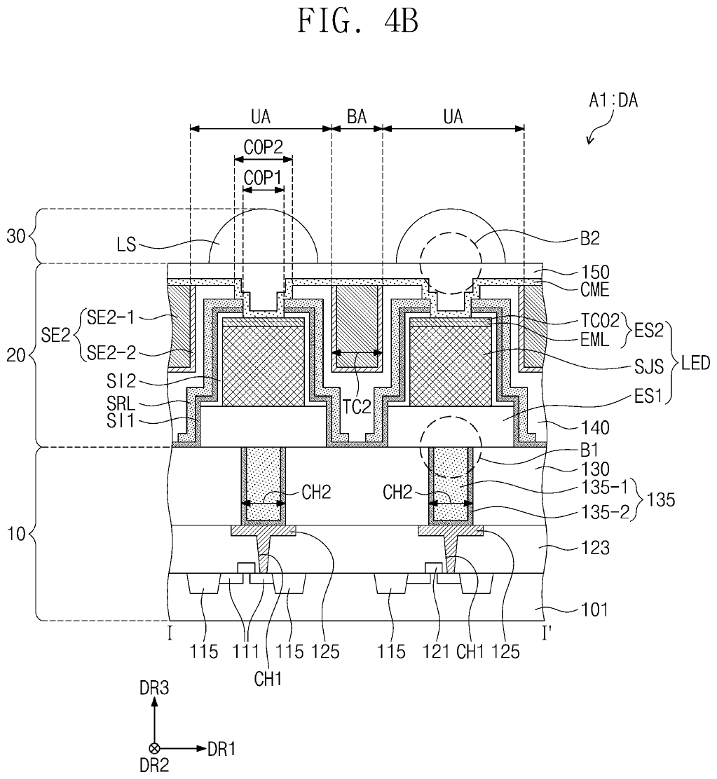

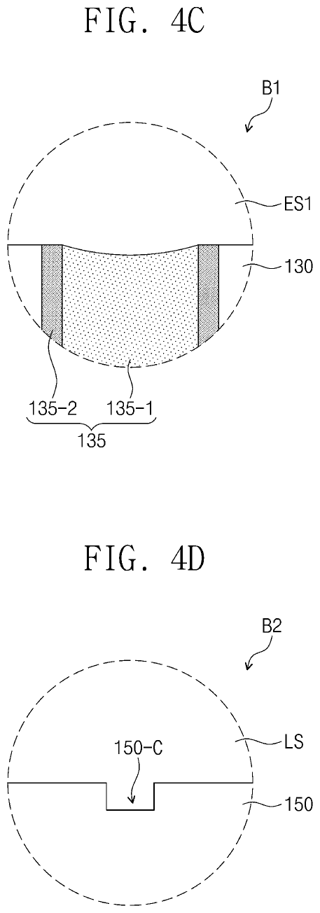

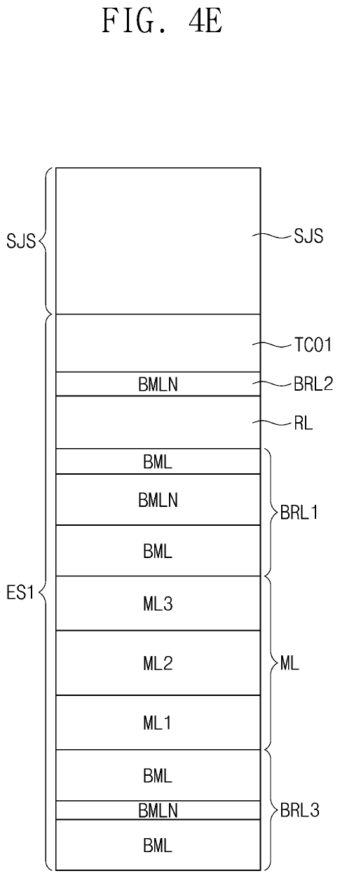

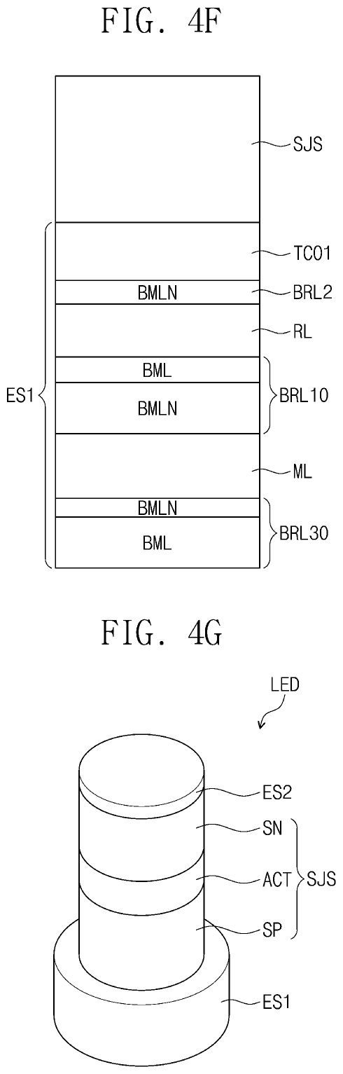

FIG. 4A is an enlarged schematic plan view illustrating a partial area of the first area of FIG. 3A. FIG. 4B is a schematic cross-sectional view taken along line I-I′ of FIG. 4A. FIG. 4C is an enlarged schematic cross-sectional view of an area B1 of FIG. 4B illustrating a contact area between a second contact electrode 135 and a first electrode member ES1. FIG. 4D is an enlarged schematic cross-sectional view of an area B2 of FIG. 4B illustrating a contact area between a passivation layer 150 and a lens LS. FIGS. 4E to 4F are schematic cross-sectional views illustrating the first electrode member ES1 of FIG. 4B. FIG. 4G is a schematic cross-sectional view illustrating the light emitting diode LED of FIG. 4B.

FIG. 4A illustrates first auxiliary electrodes SE1 and second auxiliary electrodes SE2, which cross each other, of the auxiliary electrode SE. The first auxiliary electrodes SE1 may be disposed in first trenches TC1, respectively, and the second auxiliary electrodes SE2 may be disposed in the second trenches TC2, respectively.

The first area DA may include unit areas UA and a boundary area BA between the unit areas UA. Each of the unit areas UA may be an inner area defined by two first trenches TC1 of the first trenches TC1 and two second trenches TC2 of the second trenches TC2. The boundary area BA may be an area on which the first trenches TC1 and the second trenches TC2 are disposed.

In an embodiment, the boundary area BA may be defined as an area, on which the first trenches TC1 and the second trenches TC2 are disposed, but embodiments are not limited thereto. The unit areas UA may be defined to be narrower than that defined in FIG. 4A. For example, a width of the boundary area BA may further increase. For example, the boundary area BA may be defined to have a width greater than that of each of the first auxiliary electrodes SE1 and the second auxiliary electrodes SE2.

FIG. 4A illustrates light emitting diodes LED, lenses LS, and first openings COP1, which disposed on the unit areas UA. The common electrode CME of FIG. 4B and the light emitting diodes LED of FIG. 4B are connected to each other through the first openings COP1. In a plan view, each of the first openings COP1 may be disposed inside a corresponding lens LS of the lenses LS. In the plane, each of the lenses LS may be disposed inside a corresponding light emitting diode LED.

FIG. 4B illustrates a schematic view of FIG. 2. The display device DD may include a CMOS wafer 10, a light emitting element layer 20, and a lens layer 30.

The CMOS wafer 10 may include a silicon substrate 101. Source/drain regions 111 may be defined in the silicon substrate 101. Each of the source/drain regions 111 may be a region doped with a dopant. The source/drain regions 111 may become a source of a transistor or a drain of a transistor according to a signal flow. The pair of source/drain regions 111 may define a transistor together with a gate electrode 121, which will be described later. When one of the source/drain regions (111) arranged on both sides centered on the gate electrode (121) is a source region, the other may be a drain region. The first contact electrode (125) described later is electrically connected to the source region or the drain region.

Shallow trench isolation (STI) regions 115 may be further defined in the silicon substrate 101. The STI regions 115 may prevent leakage current by isolating the transistor. The STI regions 115 may be disposed differently according to a design of the pixel circuit.

Gate electrodes 121 may be disposed on the silicon substrate 101. Each of the gate electrodes 121 may include a metal. Each of the gate electrodes 121 may be disposed to correspond to (or overlap) the pair of source/drain regions 111. A first insulating layer 123 may be disposed on the silicon substrate 101. The first insulating layer 123 may include an oxide layer such as a silicon oxide layer, a silicon nitride layer, a silicon oxynitride layer, or an aluminum oxide layer. Although the first insulating layer 123 is illustrated as a single layer, the first insulating layer 123 is not limited to the single layer.

The CMOS wafer 10 may include a first contact electrode 125. The first contact electrode 125 may be connected to the source/drain region 111 through a first contact hole CH1 defined (or formed) in the first insulating layer 123. A top surface (or upper surface) of the first contact electrode 125 may define the same plane (or flat surface) as a top surface (or upper surface) of the first insulating layer 123. The first contact electrode 125 may be formed using a damascene method. The first contact electrode 125 may include a metal such as copper or tungsten.

The second insulating layer 130 may be disposed on the first insulating layer 123. A second contact hole CH2 exposing the first contact electrode 125 may be defined (or formed) in the second insulating layer 130. The second insulating layer 130 may include an oxide layer such as a silicon oxide layer, a silicon nitride layer, a silicon oxynitride layer, or an aluminum oxide layer. Although the second insulating layer 130 is illustrated as a single layer, the second insulating layer 130 is not limited to the single layer.

The second contact electrode 135 may be disposed in the second contact hole CH2. A top surface (or upper surface) of the second contact electrode 135 may define the same plane (or flat surface) as a top surface (or upper surface) of the second insulating layer 130. The second contact electrode 135 may include a metal member 135-1 disposed inside the second contact hole and a barrier layer 135-2 disposed between a side surface of the metal member 135-1 and an inner surface of the second contact hole CH2 and disposed between a bottom surface (or lower surface) of the metal member 135-1 and a top surface (or upper surface) of the first contact electrode 125 exposed through the second contact hole CH2.

The metal member 135-1 may include a metal such as copper or tungsten. The barrier layer 135-2 may have conductivity. Coupling force between the second insulating layer 130 and the first contact electrode 125 may increase by the barrier layer 135-2, and also, the barrier layer 135-2 may prevent metal atoms of the metal member 135-1 from being diffused into the second insulating layer 130.

The barrier layer 135-2 may include a metal layer made of barrier metal (hereinafter, referred to as a barrier metal layer) and a nitride layer made of barrier metal nitride (hereinafter, referred to as a barrier metal nitride layer). The barrier metal nitride layer may be disposed closer to the second insulating layer 130 than the barrier metal layer. The barrier metal layer may improve the coupling force, and the barrier metal nitride layer may prevent atoms in the metal member 135-1 from being diffused. The barrier metal may include titanium or tantalum. The barrier layer 135-2 may include a titanium nitride layer and a titanium layer or may include a tantalum nitride layer and a tantalum layer.

In an embodiment, the second contact electrode 135 may include a tungsten structure, a titanium layer surrounding side and bottom surfaces (or lower surfaces) of the tungsten structure, and a titanium nitride layer surrounding the titanium layer. In an embodiment, the second contact electrode 135 may include a copper structure, a tantalum layer surrounding side and bottom surfaces (or lower surfaces) of the copper structure, and a tantalum nitride layer surrounding the tantalum layer.

As illustrated in FIG. 4C, in an embodiment, a top surface (or upper surface) of the second contact electrode 135 may be concave. A first electrode member ES1, which will be described later, may be in contact with the concave top surface (or concave upper surface) of the second contact electrode 135. The second contact electrode 135 may be formed by a damascene method. In a chemical mechanical polishing (CMP) process of the damascene method, the second contact electrode 135 may be polished more than the second insulating layer 130, and thus, a dishing phenomenon may occur in the second contact electrode 135.

Referring again to FIG. 4B, a light emitting diode LED may be disposed on the second insulating layer 130. The light emitting diodes LEDs illustrated in FIG. 4A may generate light having the same color. In an embodiment, one of the light emitting diodes LEDs illustrated in FIG. 4A may generate red light, another may generate green light, and the other may generate blue light. The other one may generate one of red light, green light, blue light, and white light.

The light emitting diode LED of FIG. 4B may include a first electrode, a second electrode, and an emission layer disposed between the first electrode and the second electrode. In an embodiment, the first electrode is described as the first electrode member ES1, and the second electrode is described as the second electrode member ES2. For example, the emission layer may include a semiconductor junction member SJS. For example, the light emitting diode LED according to an embodiment may include a first electrode member ES1, a semiconductor junction member SJS disposed on the first electrode member ES1, and a second electrode member ES2 disposed on the semiconductor junction member SJS. The first electrode member ES1 may be in contact with the second contact electrode 135 and may have a diameter greater than that of each of the semiconductor junction member SJS and the second electrode member ES2. In an embodiment, the semiconductor junction member SJS and the second electrode member ES2 may have the same diameter (or same size). In a plan view, the semiconductor junction member SJS and the second electrode member ES2 may be disposed inside the first electrode member ES1. In an embodiment, the first electrode member ES1 may have the same diameter (or same size) as each of the semiconductor junction member SJS and the second electrode member ES2.

In case that the light emitting diode LED has a circular shape as illustrated in FIG. 4A, the first electrode member ES1 may also have a circular shape. However, the shape of the first electrode member ES1 is not limited thereto. The first electrode member ES1 may have an oval shape or a polygonal shape such as a square or octagon.

In an embodiment, the first electrode member ES1 is described as an anode (or anode member), and the second electrode member ES2 is described as a cathode (or cathode member), but embodiments are not limited thereto. In an embodiment, the first electrode member ES1 may be a cathode, and the second electrode member ES2 may be an anode. The lamination configuration of the semiconductor junction member SJS may vary according to whether the first electrode member ES1 is the anode or the cathode.

The light emitting element layer 20 may include a first side insulating layer SI1 disposed on a side surface of the first electrode member ES1, a side surface of the semiconductor junction member SJS, a side surface of the second electrode member ES2, and a top surface (or upper surface) of the second electrode member ES2. The first side insulating layer SI1 may surround the light emitting diode LED except for the first opening COP1 and a bottom surface (or lower surface) of the first electrode member ES1.

The first side insulating layer SI1 may prevent the light emitting diode LED and a side reflective layer SRL, which will be described later, from being in contact with each other. The first side insulating layer SI1 may include a silicon oxide layer, a silicon nitride layer, a silicon oxynitride layer, an aluminum oxide layer, a zirconium oxide layer, a hafnium oxide layer, or a titanium oxide layer. In FIG. 4A, the first side insulating layer SI1 is illustrated as a single layer, but embodiments are not limited thereto. The first side insulating layer SI1 may have a single-layer structure of the above-described layers or a multi-layer structure that is arbitrarily selected from the above-described layers.

The side reflective layer SRL may be disposed outside the first side insulating layer SI1. The side reflection layer SRL may reflect light generated from the light emitting diode LED to improve light efficiency so that the light generated from the light emitting diode LED may be emitted to the first opening COP1. The side reflective layer SRL may include gold (Au), copper (Cu), silver (Ag), titanium (Ti), or aluminum (Al).

The side reflective layer SRL may be disposed to correspond to at least the side surface of the first electrode member ES1, the side surface of the semiconductor junction member SJS, and the side surface of the second electrode member ES2. A portion of the side reflective layer SRL may be further disposed on a top surface (or upper surface) of the second electrode member ES2.

In an embodiment, the side reflective layer SRL may be disposed to be spaced apart from each of the light emitting diodes LED. The side reflective layers SRL may be separated from and spaced apart from a boundary area BA. However, embodiments are not limited thereto, and the side reflective layers SRL may have various shapes. For example, the reflective layers SRL may have an integrated shape in the first area DA of FIG. 4A.

The light emitting element layer 20 may further include a second side insulating layer SI2 disposed inside the first side insulating layer SI1. The second side insulating layer SI2 may be disposed to protect a partial area of a side surface of the light emitting diode LED during a process of manufacturing the light emitting diode LED. This will be described later in detail.

The second side insulating layer SI2 may be in contact with the side surface of the semiconductor junction member SJS and the side surface of the second electrode member ES2. The second side insulating layer SI2 may be further disposed on a portion of a top surface (or upper surface) of the second electrode member ES2. The second side insulating layer SI2 may be further disposed on a portion of the top surface of the first electrode member ES1 exposed by the semiconductor junction member SJS. The second side insulating layer SI2 may include a silicon oxide layer, a silicon nitride layer, a silicon oxynitride layer, an aluminum oxide layer, a zirconium oxide layer, a hafnium oxide layer, and a titanium oxide layer. In FIG. 4A, the second side insulating layer SI2 is illustrated as a single layer, but embodiments are not limited thereto. The second side insulating layer SI2 may have a single-layer structure of the above-described layers or a multi-layer structure that is arbitrarily selected from the above-described layers.

The first opening COP1 may correspond to (or overlap) an emission area of the light emitting diode LED and may correspond to (or overlap) a passage connecting the second electrode member ES2 to the common electrode CME.

A planarization layer 140 may be disposed on the second insulating layer 130. The planarization layer 140 may overlap the unit areas UA and the boundary area (BA) and may be disposed on the light emitting diodes LEDs. The planarization layer 140 may be filled into an area on which the light emitting diodes LEDs are not disposed. The planarization layer 140 may include an organic material.

The planarization layer 140 may be disposed to correspond to (or adjacent to) the side surface of the first electrode member ES1 and the side surface of the semiconductor junction member SJS, e.g., in the first direction DR1. A portion of the planarization layer 140 may be disposed to correspond to (or adjacent to) the side surface of the second electrode member ES2, e.g., in the first direction DR1, and the other portion may be disposed on the second electrode member ES2 to overlap the side reflective layer SRL. The planarization layer 140 may be in contact with the side reflection layer SRL. A second opening COP2 corresponding to the first opening COP1 may be disposed in the planarization layer 140. The second opening COP2 may be aligned with the first opening COP1, but the second opening COP2 formed by a process different from the process of forming the first opening COP1 may have an area greater than that of the first opening COP1.

In an embodiment, the planarization layer 140 may not be disposed on the second electrode member ES2. A top surface (or upper surface) of the planarization layer 140 may define the same plane as the top surface (or upper surface) of the side reflection layer SRL. In another example, the second opening COP2 may be omitted.

In the planarization layer 140, the trenches TC1 and TC2 of FIG. 4A may be defined (or formed), and second trenches TC2 are illustrated as an example in FIG. 4B. Second auxiliary electrodes SE2 may be disposed in the second trenches TC2. The first auxiliary electrodes SE1 illustrated in FIG. 4A may be formed by the same process, by which the second auxiliary electrodes SE2 is formed, and may have the same structure as the second auxiliary electrodes SE2 to be described later.

The second auxiliary electrode SE2 may include a metal member SE2-1 disposed inside the second trench TC2 and a barrier layer SE2-2 disposed between the metal member SE2-1 and the second trench TC2. The metal member SE2-1 may include a metal such as copper or tungsten. The barrier layer SE2-2 may have conductivity like the metal member SE2-1. Coupling force to the planarization layer 140 may increase by the barrier layer SE2-2, and the barrier layer SE2-2 may prevent metal atoms of the metal member SE2-1 from being diffused into the planarization layer 140.

The barrier layer SE2-2 may include a barrier metal layer and a barrier metal nitride layer. The barrier metal nitride layer may be disposed closer to the planarization layer 140 than the barrier metal layer. The barrier metal layer may include titanium or tantalum. The barrier metal nitride layer may include a titanium nitride layer or a tantalum nitride layer. The second auxiliary electrode SE2 may also be formed using a damascene method like the second contact electrode 135, and a top surface (or upper surface) of the second auxiliary electrode SE2 may be concave.

A common electrode CME may be disposed on the planarization layer 140. The common electrode CME may overlap the unit areas UA and the boundary area BA. The common electrode CME may include a transparent conductive material to emit light generated by a light emitting diode LED. The common electrode CME may include transparent conductive oxide such as indium tin oxide (ITO), indium zinc oxide (IZO), zinc oxide (ZnO), zinc tin oxide (ZTO), or indium gallium zinc oxide (IGZO).

The common electrode CME may be connected to the second electrode members ES2 of the light emitting diodes LED through the first openings COP1 and the second openings COP2. A power voltage applied through the common electrode CME may be transmitted to the light emitting diode LED. FIG. 4B illustrates a common electrode CME connected to two light emitting diodes LED as an example. One of the two light emitting diodes LED may be defined as the first light emitting diode LED, and the other may be defined as the second light emitting diode LED.

The common electrode CME may be in contact with a top surfaces (or upper surface) of the second auxiliary electrodes SE2. Since the top surface (or upper surface) of the second auxiliary electrodes SE2 is in contact with the common electrode CME along a longitudinal direction of the second trench TC2 as illustrated in FIG. 4A, the common electrode CME and the second auxiliary electrodes SE2 may ensure a sufficient contact area.

A passivation layer 150 may be disposed on the common electrode CME. The passivation layer 150 may protect the common electrode CME. The passivation layer 150 may overlap the display area DA and the non-display area NDA of FIGS. 3A and 3B to protect a voltage transmission electrodes VTE. The passivation layer 150 may include an organic material or an inorganic material.

Lenses LS may be disposed on the passivation layer 150. Two lenses LS corresponding to the first and second light emitting diodes LED are illustrated. The lenses LS concentrate light emitted from light emitting diodes LED. The lenses LS may include an organic material and have a hemispherical shape. The lenses LS may have a diameter of about 1 micrometer or less.

As illustrated in FIGS. 4B and 4D, the passivation layer 150 may include a concave region 150-C. A stepped portion may be disposed in a region corresponding to the first opening COP1 of FIG. 4B, and the stepped portion may be transferred to each of the common electrode CME and the passivation layer 150. The stepped portion may be removed according to a material or thickness of the passivation layer 150.

Hereinafter, a laminated structure of the first electrode member ES1 will be described in detail with reference to FIGS. 4E and 4F. For example, in the first electrode member ES1 according to an embodiment, some layers may be omitted from the structure illustrated in FIGS. 4E and 4F, or other functional layers may be further provided.

Referring to FIG. 4E, the first electrode member ES1 may include at least a metal layer ML, a reflective layer RL disposed on the metal layer ML, and a transparent conductive oxide layer TCO1 (hereinafter, referred to as a first transparent conductive oxide layer) disposed on the reflective layer RL. The metal layer ML, the reflective layer RL, and the first transparent conductive oxide layer TCO1 may be sequentially laminated, or additional functional layers may be further disposed between the metal layer ML, the reflective layer RL, and the first transparent conductive oxide layer TCO1.

The metal layer ML may correspond to an adhesive layer that bonds the CMOS wafer to the semiconductor substrate during the process of manufacturing the display device. For example, the metal layer ML may be a layer formed by coupling a metal portion of the CMOS wafer to a metal portion of the semiconductor substrate.

The metal layer ML may include at least one metal layer. At least one metal layer may include any one of gold (Au), copper (Cu), silver (Ag), tin (SN), titanium (Ti), zirconium (Zr), and tantalum (Ta), or may include an alloy of two metals of the above-described metals.

In an embodiment, a triple metal layer ML including first to third metal layers ML1, ML2, and ML3 is illustrated as an example. The second metal layer ML2 may include any one of gold (Au), copper (Cu), silver (Ag), tin (SN), titanium (Ti), zirconium (Zr), and tantalum (Ta) and also may include a metal different from the first and third metal layer ML1 and ML3. Each of the first and third metal layers ML1 and ML3 may include one of (Au), copper (Cu), silver (Ag), tin (SN), titanium (Ti), zirconium (Zr), and tantalum (Ta). In an embodiment, the metal layer ML may include two consecutive metal layers of the first to third metal layers ML1, ML2, and ML3.

The reflective layer RL may reflect light generated in the semiconductor junction member SJS in a direction of the semiconductor junction member SJS. The reflective layer RL may include gold (Au), copper (Cu), silver (Ag), titanium (Ti), or aluminum (Al).

The first transparent conductive oxide layer TCO1 may inject holes into the semiconductor junction member SJS. The first transparent conductive oxide layer TCO1 may have a high work function, which is advantageous for the hole injection, and may transmit light reflected from the reflection layer RL. The first transparent conductive oxide layer TCO1 may include at least one of indium tin oxide (ITO), indium zinc oxide (IZO), zinc oxide (ZnO), zinc tin oxide (ZTO), or indium gallium zinc oxide (IGZO).

In an embodiment, the first electrode member ES1 may be described as an anode and may have the above-described structure. However, in case that the first electrode member ES1 is the cathode, the structure of the first electrode member ES1 may be changed. An electron injection functional layer and the reflective layer may be integrated as a single metal layer. For example, the metal layer functions as both the electron injection layer and the reflection layer. Thus, the cathode member may include two metal layer that are distinguished from each other.

The first electrode member ES1 may have a thickness of about 500 nm or less. As the thickness of the first electrode member ES1 increases, process errors according to the thickness may occur. For example, an etch rate may vary according to the thickness. In case that the thickness of the first electrode member ES1 is thick, the first electrode member ES1 may be provided to have a more inclined side surface. In order to form the first electrode member ES1 having a vertical side surface, the first electrode member ES1 may have a thickness of about 500 nm or less.

According to FIG. 4E, the first electrode member ES1 may include a first barrier layer BRL1 disposed between the metal layer ML and the reflective layer RL, a second barrier layer BRL2 disposed between the reflective layer RL and the first transparent conductive oxide layer TCO1, and a third barrier layer BRL3 disposed below the metal layer ML. Each of the first to third barrier layers BRL1 to BRL3 may include a barrier metal layer and a barrier metal nitride layer. The barrier metal layer may improve adhesion between adjacent layers, and the barrier metal nitride layer may prevent atoms in the adjacent layers from being diffused.

In an embodiment, the first barrier layer BRL1 may include a barrier metal nitride layer BMLN including a barrier metal nitride e.g., titanium nitride and barrier metal layers BML respectively disposed above and below the barrier metal nitride layer BMLN. The barrier metal layers BML contains a barrier metal e.g., titanium. For example, the titanium nitride layer may prevent electromigration from occurring in the reflective layer RL by blocking the metal atoms of the metal layer ML from moving to the reflective layer RL.

In an embodiment, the second barrier layer BRL2 may include a barrier metal nitride layer BMLN including titanium nitride. For example, the titanium nitride layer may block the atomic movement between the first transparent conductive oxide layer TCO1 and the reflective layer RL to prevent voids from being generated in the first transparent conductive oxide layer TCO1 or prevent the reflective layer RL from being oxidized.

In an embodiment, the third barrier layer BRL3 may include a barrier metal nitride layer BMLN including titanium nitride and barrier metal layers BML respectively disposed above and below the barrier metal nitride layer BMLN and including titanium. The electromigration may be prevented from occurring between the second contact electrode 135 and the metal layer ML in FIG. 4B.

FIG. 4F illustrates a first electrode member ES1 having a relatively simply laminated structure compared to that in FIG. 4E. The metal layer ML may include a single metal layer. The first barrier layer BRL10 may include a barrier metal nitride layer BMLN and a barrier metal layer BML disposed on the barrier metal nitride layer BMLN. The third barrier layer BRL30 may include a barrier metal nitride layer BMLN and a barrier metal layer BML disposed below the barrier metal nitride layer BMLN made of the barrier metal. The barrier metal nitride layer BMLN of the first barrier layer BRL10 may be in contact with a top surface (or upper surface) of the metal layer ML, and the barrier metal nitride layer BMLN of the third barrier layer BRL30 may be in contact with a bottom surface (or lower surface) of the metal layer ML.

The laminated structure of FIG. 4F may be formed by allowing specific layers to include the same material in the laminated structure of FIG. 4E. For example, in case that the metal layer ML of FIG. 4E has a single-layer structure of titanium (Ti), and the barrier metal layer BML of the first and third barrier layers BRL1 and BRL3 includes titanium (Ti), the barrier metal layer BML of the first and third barrier layers BRL1 and BRL3 adjacent to the metal layer ML and the metal layer ML may be provided as a single metal layer.

The light emitting diode LED will be described in detail with reference to FIG. 4G. In FIG. 4G, the first electrode member ES1 is illustrated as a single layer, and the semiconductor junction member SJS is illustrated in detail. Although the disk-shaped first electrode member ES1 is illustrated as an example, the shape of the first electrode member ES1 is not limited thereto. In an embodiment, the light emitting diode LED may have a cylindrical shape, but embodiments are not limited thereto.

The semiconductor junction member SJS may include an active layer ACT, a p-type semiconductor layer SP disposed at a side of the active layer ACT, and an n-type semiconductor layer SN disposed at another side of the active layer ACT. In an embodiment, since the first electrode member ES1, which is the anode, is disposed below the active layer ACT, the p-type semiconductor layer SP may be disposed below the active layer ACT.

The active layer ACT may be provided in a single-quantum well structure or a multi-quantum well structure. Light may be emitted by coupling electron-hole pairs according to an electrical signal applied through the p-type semiconductor layer SP and the n-type semiconductor layer SN. The active layer ACT may emit light having a wavelength of about 400 nm to about 900 nm and may use a double hetero-structure.

In an embodiment, the active layer ACT may have a structure in which a type of semiconductor material having large band gap energy and a semiconductor material having small band gap energy are alternately laminated and may include Group 3 to Group 5 semiconductor materials selected according to the wavelength of the emitted light.

The p-type semiconductor layer SP may include at least one semiconductor material selected from InAlGaN, GaN, AlGaN, InGaN, AlN, and InN and may be doped with a first conductive dopant such as magnesium (Mg), zinc (Zn), calcium (Ca), or barium (Ba). For example, the p-type semiconductor layer SP may be p-GaN doped with magnesium (Mg). However, the material forming the p-type semiconductor layer SP is not limited thereto, and the p-type semiconductor layer SP may be formed by various other materials.

The n-type semiconductor layer SN may include at least one semiconductor material selected from InAlGaN, GaN, AlGaN, InGaN, AlN, and InN and may be doped with a second conductive material such as silicon (Si), zimanium (Ge), or tin (SN). However, the material forming the n-type semiconductor layer SN is not limited thereto, and the n-type semiconductor layer SN may be formed by various other materials.

For example, the light emitting diode LED may further include a clad layer. The clad layer may be disposed above and/or below the active layer ACT. The clad layer may include an AlGaN layer or an InAlGaN layer. The light emitting diode LED may further include a tensile strain barrier reducing (TSBR) layer disposed above and/or below the active layer ACT. The TSBR layer may be a strain relaxation layer that is disposed between semiconductor layers having different lattice structures to function as a buffer to reduce a lattice constant difference. The TSBR layer may be provided as a p-type semiconductor layer such as p-GaInP, p-AlInP, p-AlGaInP, etc., but embodiments are not limited thereto.

In an embodiment, the second electrode member ES2 may include a transparent conductive oxide layer (hereinafter, referred to as a second transparent conductive oxide layer). The second transparent conductive oxide layer TCO2 may include indium tin oxide (ITO), indium zinc oxide (IZO), zinc oxide (ZnO), zinc tin oxide (ZTO), or indium gallium zinc oxide (IGZO). The second transparent conductive oxide layer TCO2 may correspond to a protective layer in the process of manufacturing the light emitting diode LED and may inject electrons into the semiconductor junction member SJS. A detailed description of the role of the second transparent conductive oxide layer TCO2 as the protective layer will be described later with reference to the manufacturing method.

The second electrode member ES2 may further include an electrode metal layer EML disposed between the second transparent conductive oxide layer TCO2 and the semiconductor junction member SJS. The electrode metal layer EML may include a metal having a work function less than that of the second transparent conductive oxide layer TCO2. The electrode metal layer EML may improve electron injection performance of the second electrode member ES2. The electrode metal layer EML may include aluminum (Al), titanium (Ti), indium (In), gold (Au), silver (Ag), nickel (Ni), copper (Cu), oxides thereof, or an alloy thereof.

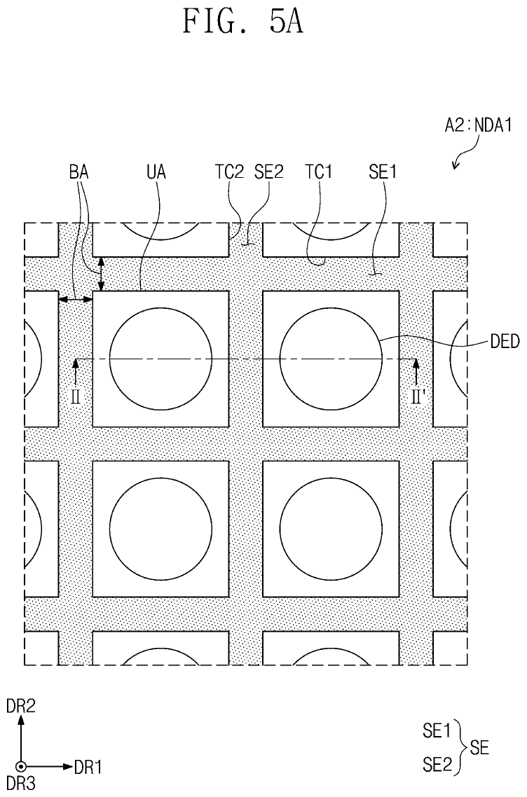

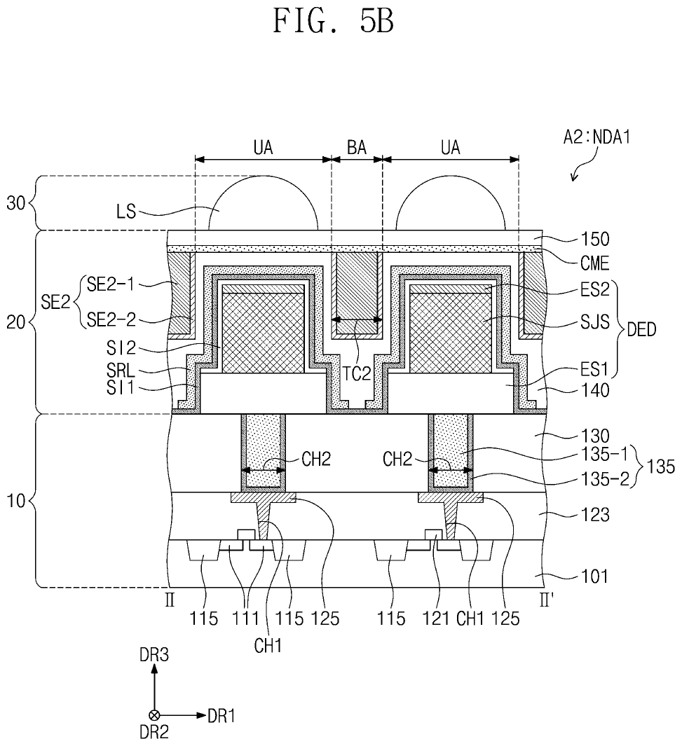

FIG. 5A is an enlarged schematic plan view illustrating a partial area A2 of a second area NDA1 of FIG. 3A. FIG. 5B is a schematic cross-sectional view taken along line II-II′ of FIG. 5A. Hereinafter, description will focus on a differences from the partial area A1 of the first area DA described with reference to FIGS. 4A to 4D.

Referring to FIG. 5A, the first auxiliary electrodes SE1 may be respectively disposed in the first trenches TC1 in the second area NDA1, and the second auxiliary electrodes SE2 may be respectively disposed in the second trenches TC2 in the second area NDA1. The first auxiliary electrodes SE1 may extend from the first auxiliary electrodes SE1 of FIG. 4A, and the second auxiliary electrodes SE2 may extend from the second auxiliary electrodes SE2 of FIG. 4A.

The second area NDA1 may include unit areas UA and a boundary area BA between the unit areas UA. An arrangement relationship between the unit areas UA and the boundary area BA of the third area NDA2 may be the same as the arrangement relationship between the unit areas UA and the boundary area BA of the second area NDA1. Dummy light emitting diodes DEDs may be disposed on the unit areas UA of the second area NDA1, and the lenses LS and the first openings COP1 may not be disposed.

The dummy light emitting diode DED illustrated in FIG. 5B may have substantially the same laminated structure as the light emitting diode LED illustrated in FIG. 4B. This is because the dummy light emitting diodes DEDs and the light emitting diodes LEDs are formed by the same process. The second electrode member ES2 of the dummy light emitting diode DED may not be exposed to the outside and may not be connected to the common electrode CME. This is because the first opening COP1 is not defined (or formed) in the first side insulating layer SI1, the second side insulating layer SI2, and the side reflective layer SRL. Thus, the dummy light emitting diode DED may not be driven or may not emit light.

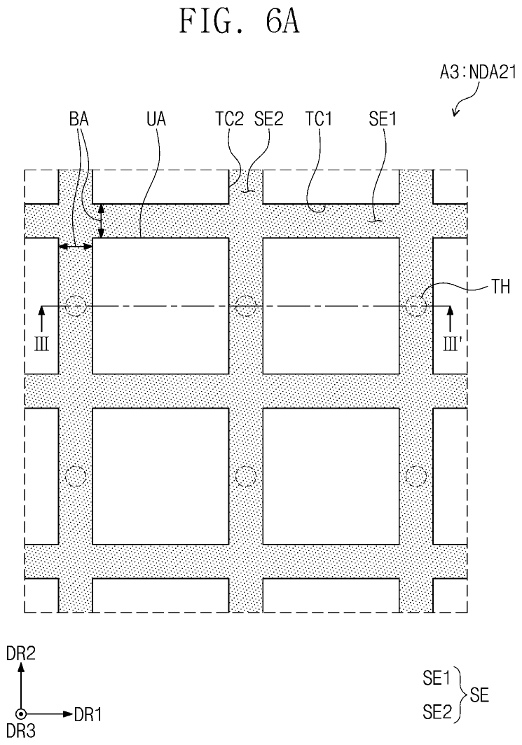

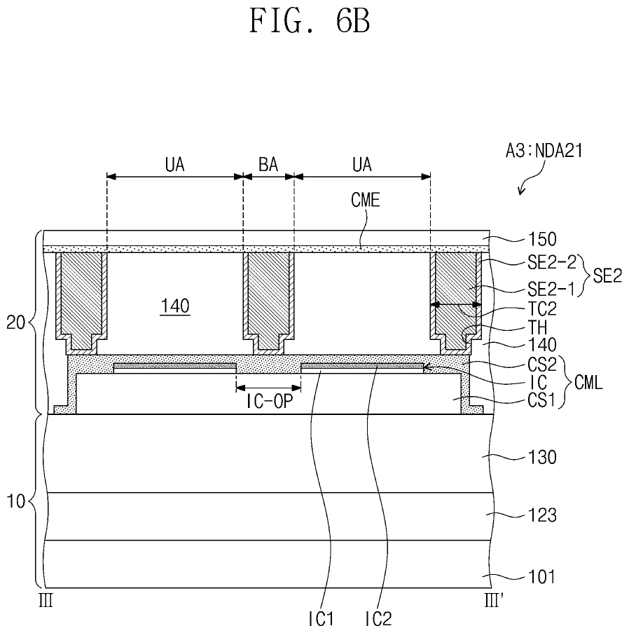

FIG. 6A is an enlarged schematic plan view illustrating a partial area A3 of a third-1 area NDA21 of FIG. 3A. FIG. 6B is a schematic cross-sectional view taken along line III-III′ of FIG. 6A. Hereinafter, description will focus on a difference between the partial area A1 of the above-described first area DA and the partial area A2 of the second area NDA1.

Referring to FIG. 6A, the first auxiliary electrodes SE1 may be respectively disposed in the first trenches TC1 in the third-1 area NDA21, and the second auxiliary electrodes SE2 may be respectively disposed in the second trenches TC2 in the third-1 area NDA21. The first auxiliary electrodes SE1 may extend from the first auxiliary electrodes SE1 of FIG. 5A, and the second auxiliary electrodes SE2 may extend from the second auxiliary electrodes SE2 of FIG. 5A.

The third-1 area NDA21 may include unit areas UA and a boundary area BA between the unit areas UA. An arrangement relationship between the unit areas UA and the boundary area BA of the third-1 area NDA21 may be the same as the arrangement relationship between the unit areas UA and the boundary area BA of the second area NDA1. The light emitting diodes LED or the dummy light emitting diodes DED may not be disposed on the unit areas UA of the third-1 area NDA21, and the lenses LS and the first openings COP1 may not be disposed on the unit areas UA of the third-1 area NDA21.

Referring to FIG. 6B, the CMOS wafer 10 is illustrated to include only a silicon substrate 101, a first insulating layer 123, and a second insulating layer 130. However, a scan driver may be formed on the third-1 area NDA21 of the CMOS wafer 10, and the scan driver may be a circuit including transistors similar to the transistors illustrated in FIG. 4B.

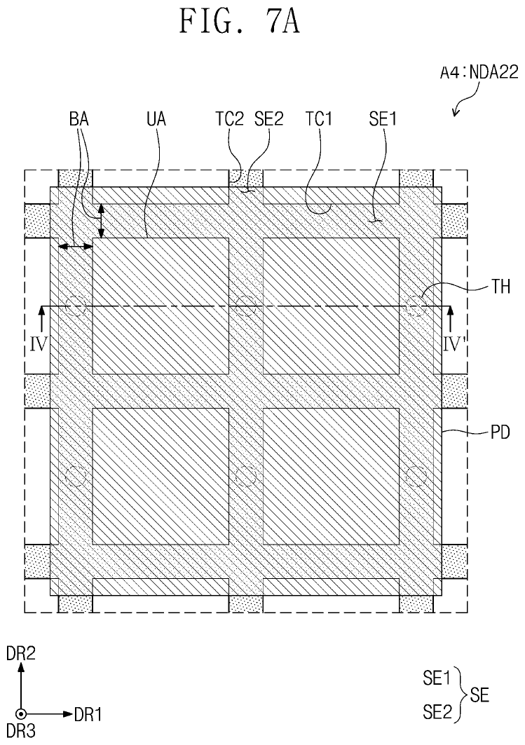

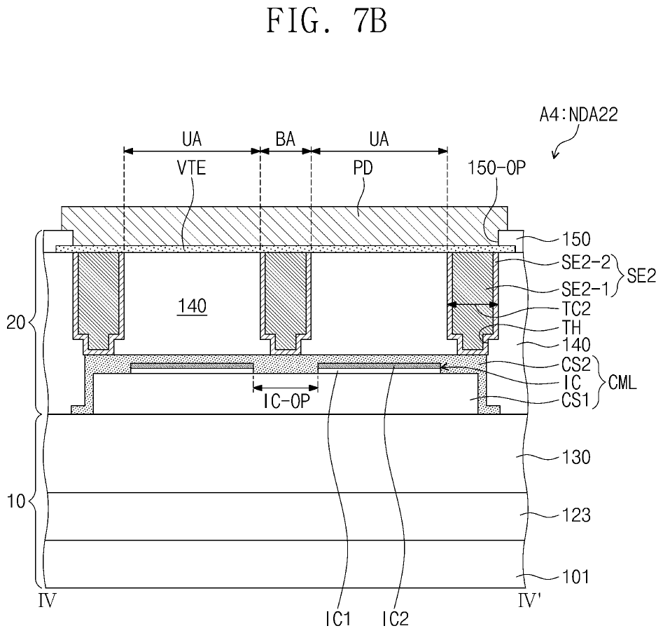

A common line CML may be disposed on the second insulating layer 130 in the third-1 area NDA21. The common line CML may be electrically connected to the common electrode CME in the third-1 area NDA21. For example, the common line CML may not only overlap the third-1 area NDA21 but also extend to overlap the voltage transmission electrodes VTE, as will be described later with reference to FIG. 7B.

The common line CML may include a first conductive member CS1 having the same laminated structure as the first electrode member ES1 of FIG. 4B. The common line CML may further include an insulating member IC disposed on a top surface (or upper surface) of the first conductive member CS1. The insulating member IC may include a first insulating pattern layer IC1 formed by the same process, by which the second side insulating layer SI2 is formed, and a second insulating pattern layer IC2 formed by the same process, by which the first side insulating layer SI1 is formed. The second insulating pattern layer IC2 may or may not be in contact with a side surface of the first conductive member CS1. An opening IC-OP may be defined (or formed) in the insulating member IC, and in an embodiment, the insulating member IC may be omitted.

The common line CML may be disposed on the first conductive member CS1 and may further include a second conductive member CS2 electrically connected to the first conductive member CS1. The second conductive member CS2 may be connected to the side surface of the first conductive member CS1 and may be connected to a top surface (or upper surface) of the first conductive member CS1 through the opening IC-OP of the insulating member IC. The second conductive member CS2 may be formed by the same process, by which the side reflective layer SRL of FIG. 4B is formed, and may include the same material. The second conductive member CS2 may be spaced apart from and electrically insulated from the side reflective layer SRL of FIGS. 4B and 5B.

In an embodiment, the common interconnection CML including the first conductive member CS1, the insulating member IC, and the second conductive member CS2 is illustrated as an example, but the common interconnection CML is not limited thereto. As described above, the common line CML may include only the first conductive member CS1 or may include the first conductive member CS1 and the insulating member IC.

The common line CML may be connected to the common electrode CME through the auxiliary electrode SE of FIG. 3B, for example, the second auxiliary electrodes SE2 of FIG. 6B. The second auxiliary electrodes SE2 may be respectively disposed in the second trenches TC2. A through-hole TH extending from an area of the second trenches TC2 may be defined (or formed) in the planarization layer 140. The second auxiliary electrodes SE2 may be connected to the common line CML through the through-hole TH.

FIGS. 6A and 6B illustrate that the through-holes TH are defined (or formed) to overlap the second trenches TC2 as an example, but embodiments are not limited thereto. The through-holes TH may be further defined (or formed) to overlap the first trenches TC1 of FIG. 6A, and their number, shape, and location are not limited.

FIG. 7A is an enlarged schematic plan view illustrating a partial area A4 of a third-2 area NDA22 of FIG. 3A. FIG. 7B is a schematic cross-sectional view taken along line IV-IV′ of FIG. 7A. Hereinafter, description will focus on a difference from the partial area A3 of the third-1 area NDA21 described above.

FIG. 7A illustrates the partial area A4 on which the pad electrode PD is disposed on the third-2 area NDA22 of FIG. 3A. The first auxiliary electrodes SE1 may be respectively disposed in the first trenches TC1 in the third-2 area NDA22, and the second auxiliary electrodes SE2 may be respectively disposed in the second trenches TC2 in the third-2 area NDA22. The first auxiliary electrodes SE1 may extend from the first auxiliary electrodes SE1 of FIG. 6A, and the second auxiliary electrodes SE2 may extend from the second auxiliary electrodes SE2 of FIG. 6A. The third-2 area NDA22 may include unit areas UA and a boundary area BA between the unit areas UA. The pad electrode PD may overlap a portion of the unit areas UA and a portion of the boundary areas BA.

An area the third-2 area NDA22 of FIG. 3A, which overlaps the voltage transmission electrode VTE, may have the same structure as the partial area A4 illustrated in FIGS. 7A and 7B, except for the pad electrode PD. However, an area of the third-2 area NDA22, which does not overlap the voltage transmission electrode VTE, may have a different structure from the partial area A4 illustrated in FIGS. 7A and 7B. The first auxiliary electrodes SE1, the first trenches TC1, the second auxiliary electrodes SE2, and the second trenches TC2 may not be disposed on the area of the third-2 area NDA22, which does not overlap the voltage transmission electrode VTE.

The common line CML of FIG. 7B may extend from the third-1 area NDA21 of FIGS. 6A and 6B to the third-2 area NDA22 along the voltage transmission electrode VTE. The common line CML may be connected to the voltage transmission electrode VTE through the second auxiliary electrodes SE2. The second auxiliary electrode SE2 disposed in the second trenches TC2 may be connected to the common line CML through the through-hole TH defined (or formed) in the planarization layer 140.

An opening 150-OP exposing a partial area (hereinafter, referred to as a connection area) of the voltage transmission electrode VTE may be defined (or formed) in the passivation layer 150. The pad electrode PD disposed on the passivation layer 150 may be connected to the connection area of the voltage transmission electrode VTE through the opening 150-OP.

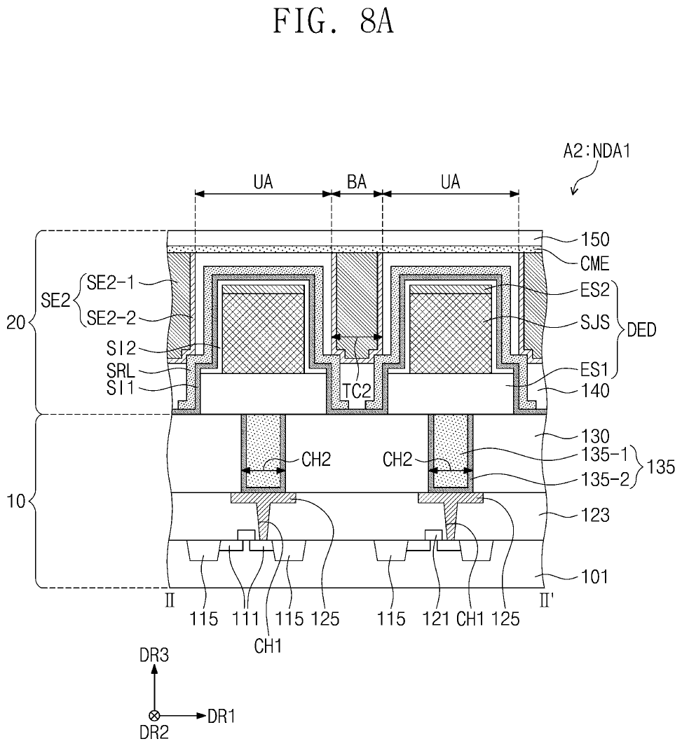

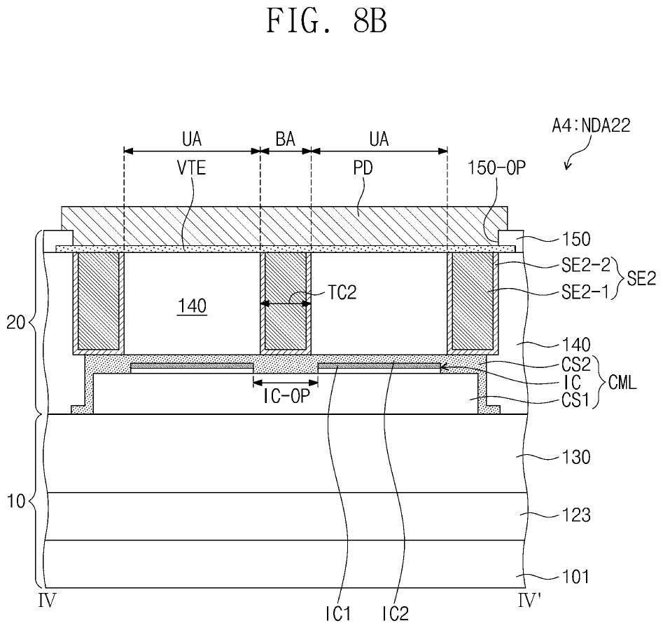

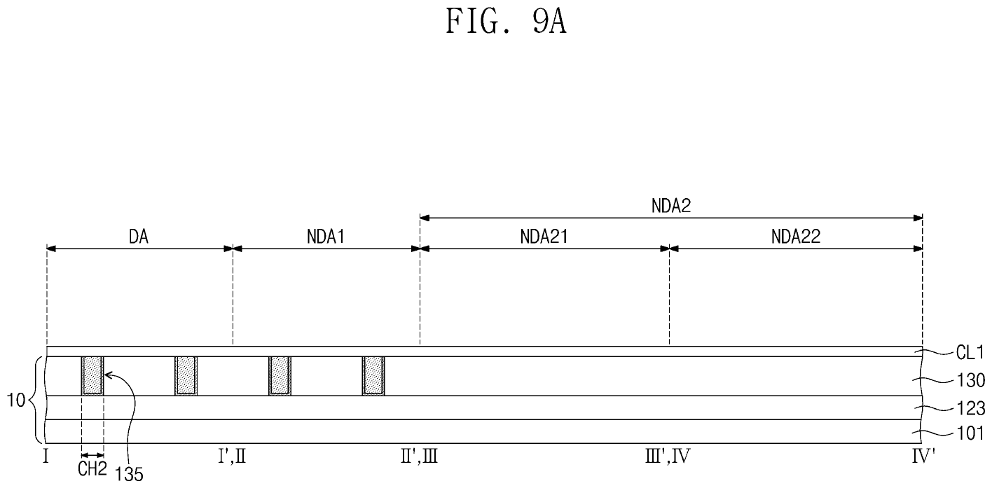

FIG. 8A is a schematic cross-sectional view corresponding to a second area NDA1 according to an embodiment. FIG. 8B is a schematic cross-sectional view corresponding to a third-2 area NDA22. FIG. 8A is a schematic cross-sectional view corresponding that of FIG. 5B, and FIG. 8B is a schematic cross-sectional view corresponding to that of FIG. 7B.

For example, the second trench TC2 formed in the first area DA of FIG. 4B may also be modified like the second trench TC2 of FIG. 8A, and the second trench TC2 formed in the third-1 area NDA21 of FIG. 7B may also be modified like the second trench TC2 of FIG. 8B.

The second trench TC2 of FIG. 8A may be formed deeper than the second trench TC2 illustrated in FIGS. 4B and 5B. Thus, a portion of the side reflective layer SRL may be exposed by the second trench TC2 in FIG. 8A. The second auxiliary electrodes SE2 may be in contact with the side reflective layer SRL.

The second trench TC2 in FIG. 8B may be also formed deeper than the second trench TC2 illustrated in FIGS. 6B and 7B. Thus, the through-hole TH in FIGS. 6B and 7B, which has been additionally formed in some areas may be omitted. For example, a contact area between the second auxiliary electrodes SE2 and the common line CML may further increase.

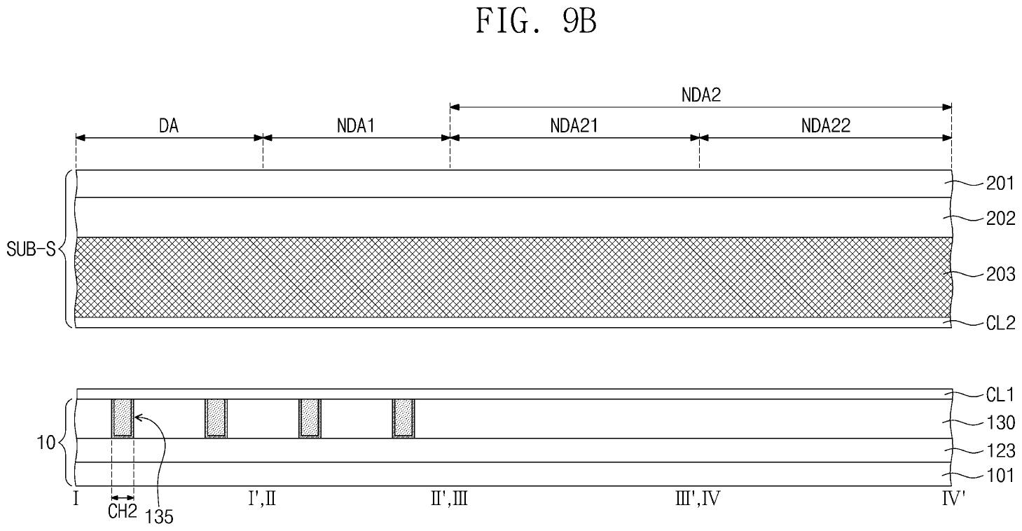

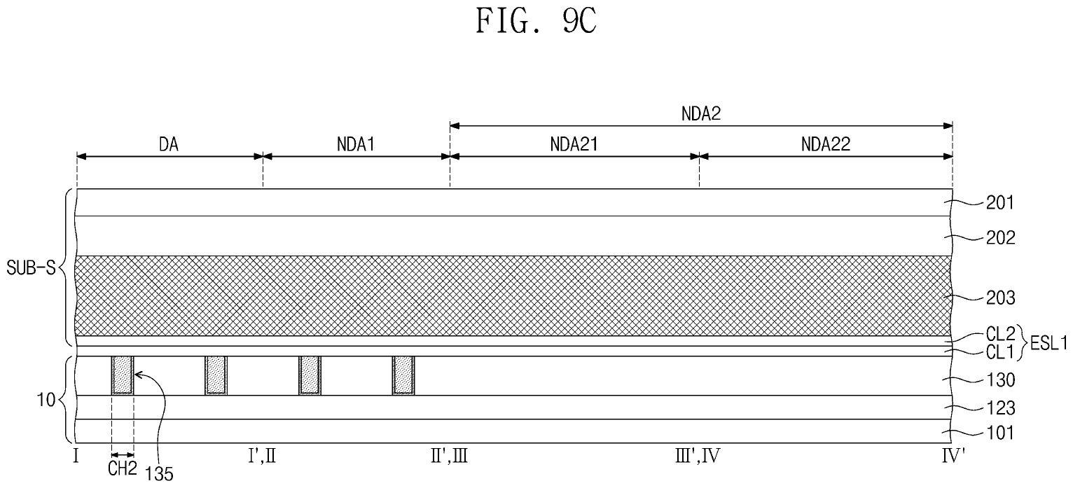

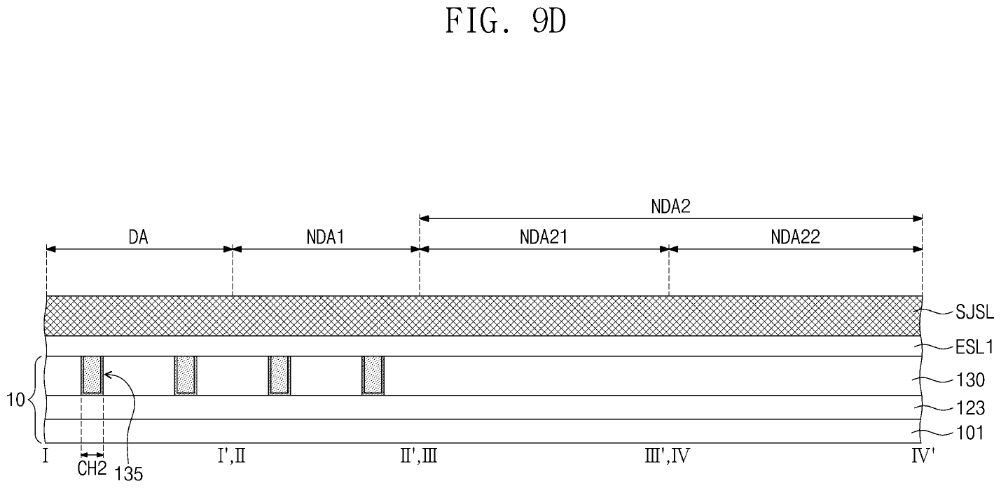

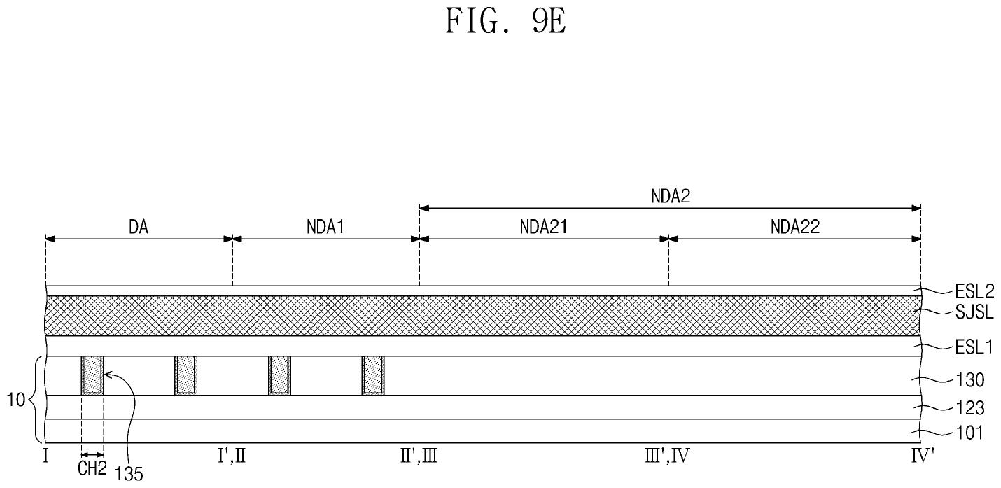

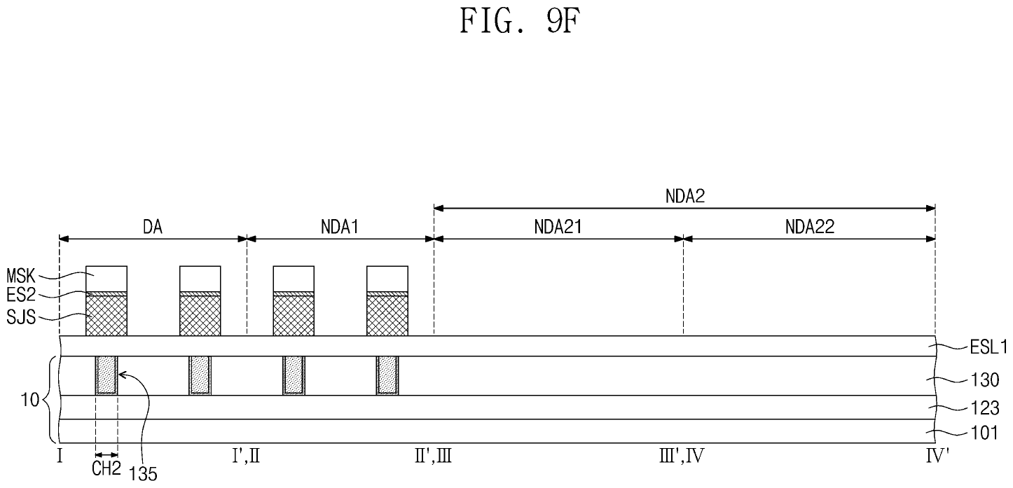

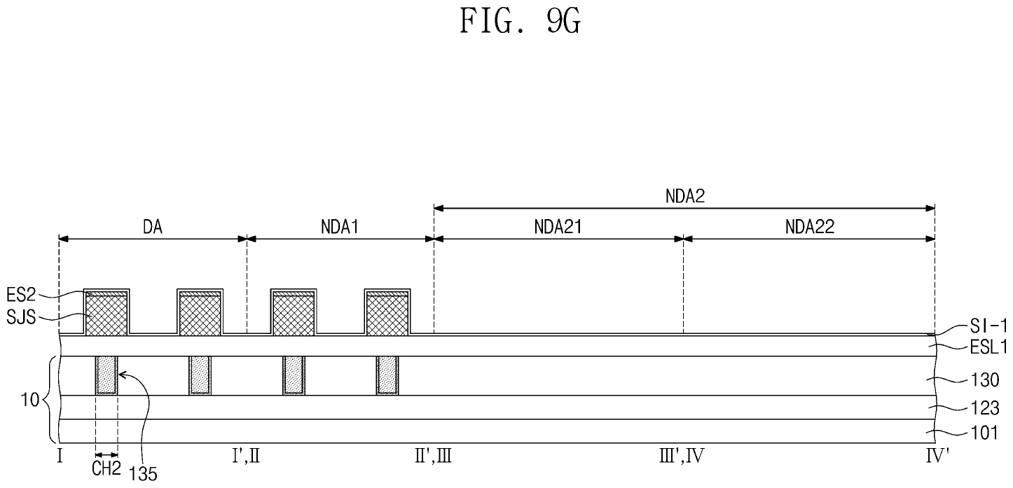

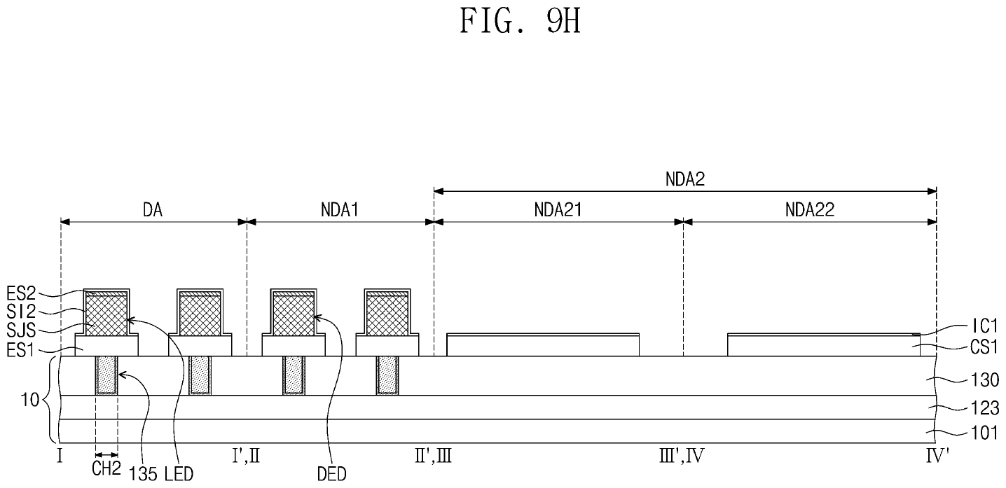

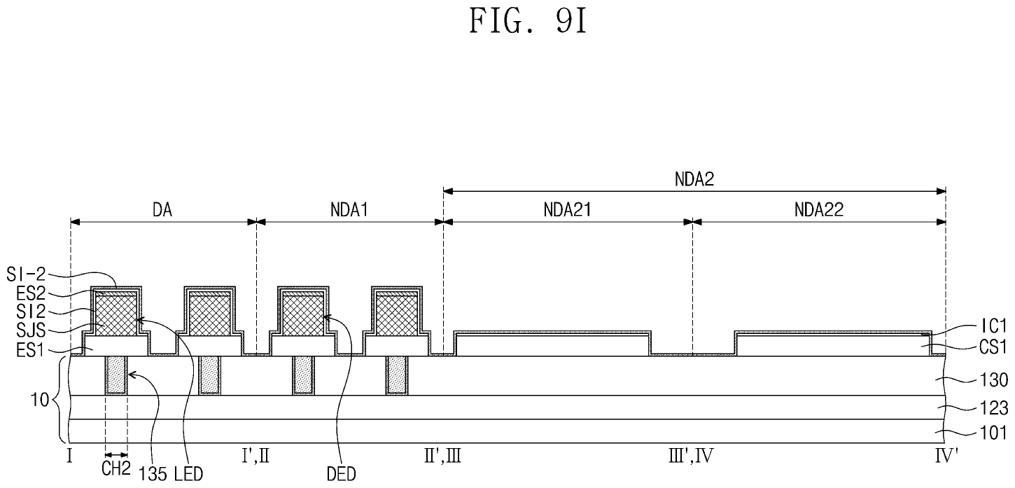

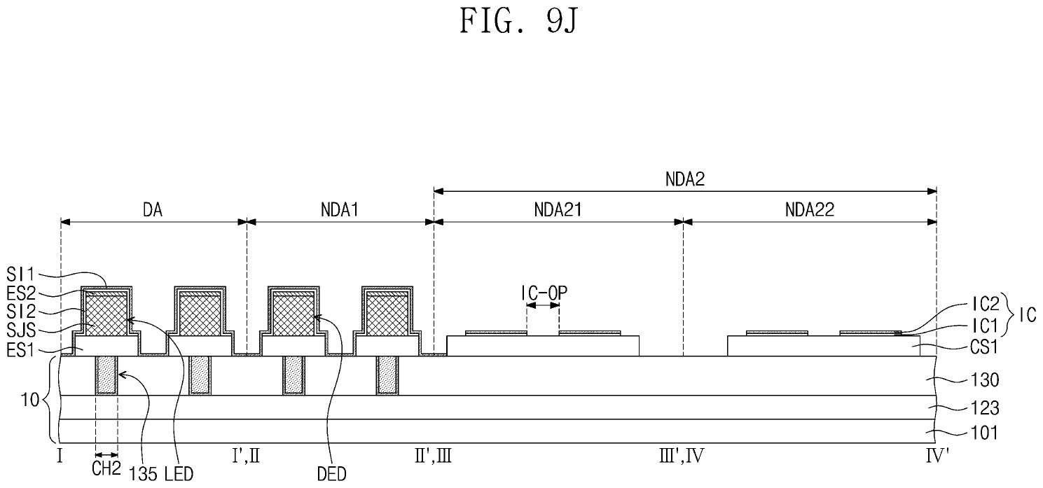

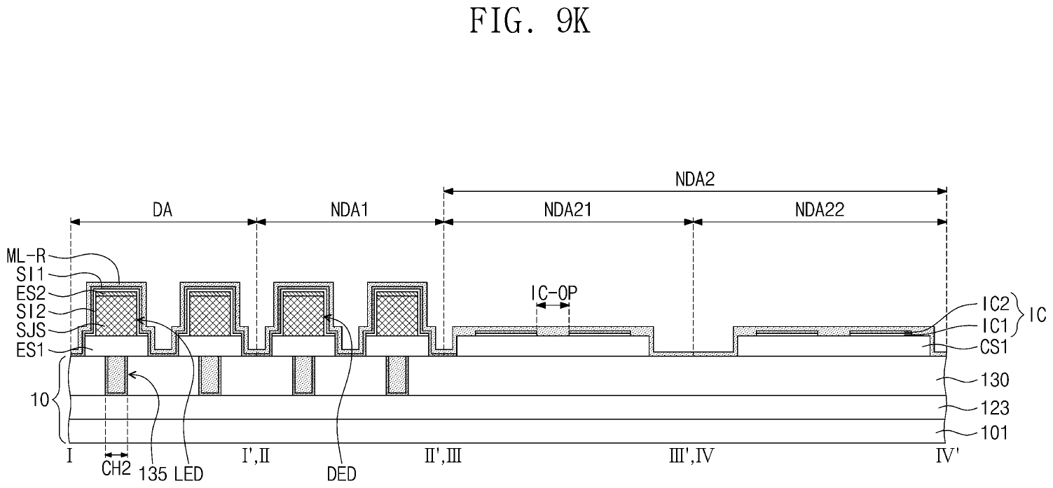

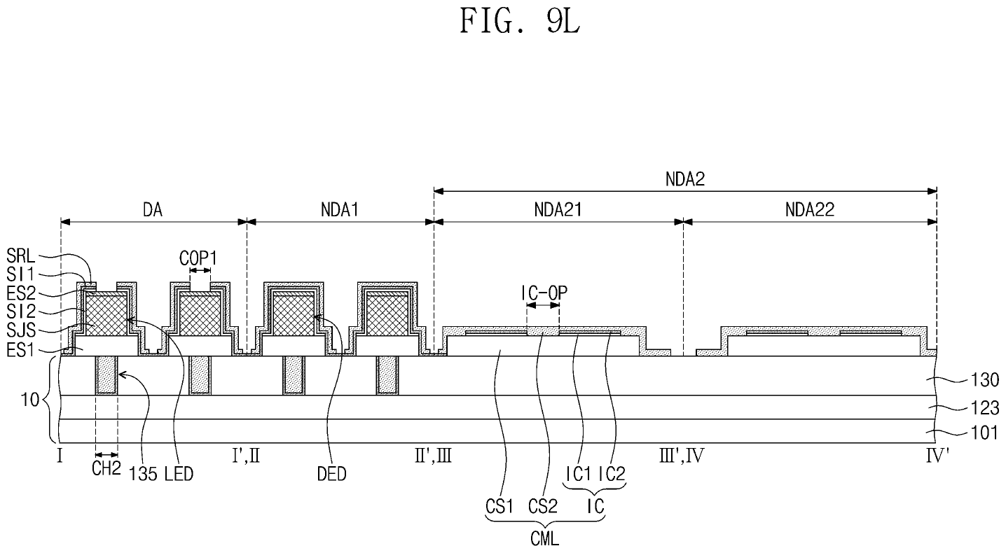

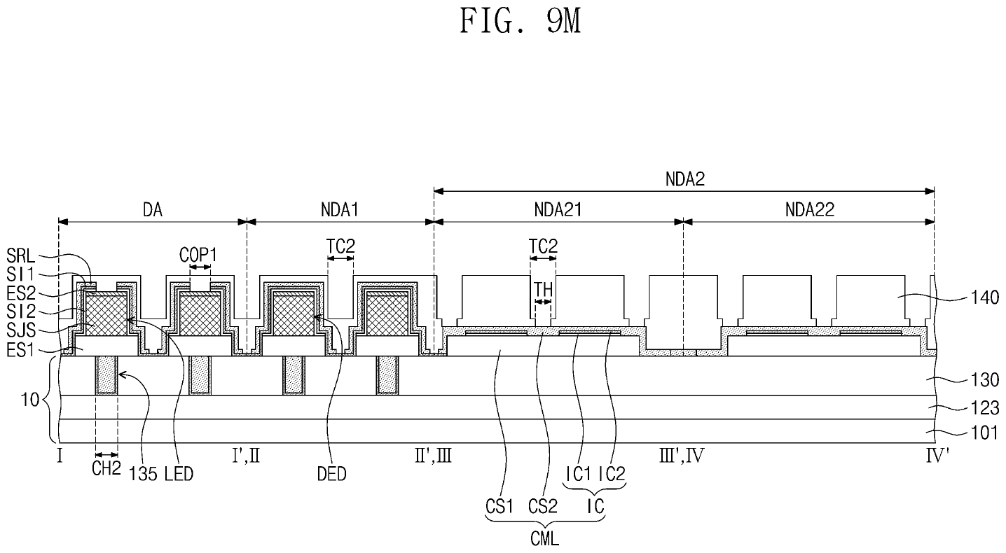

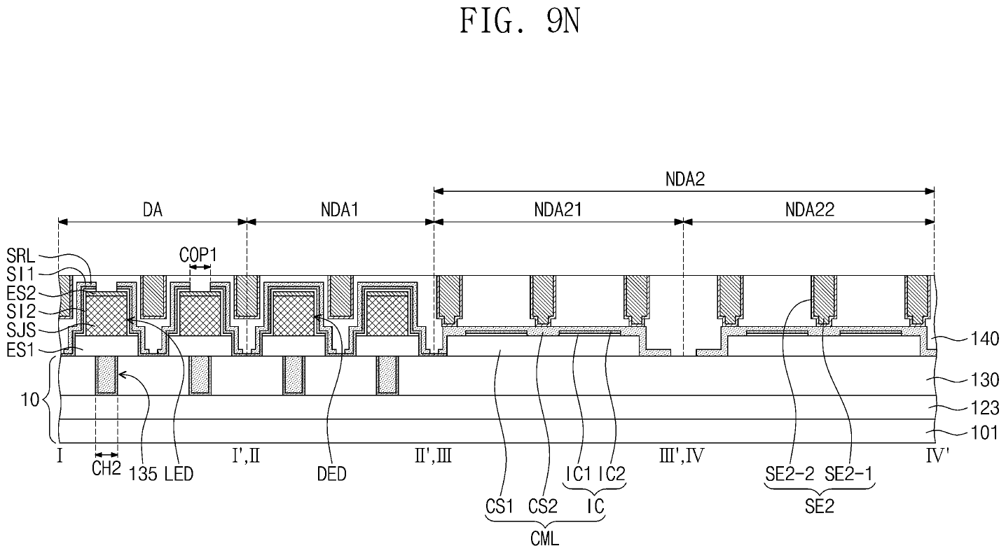

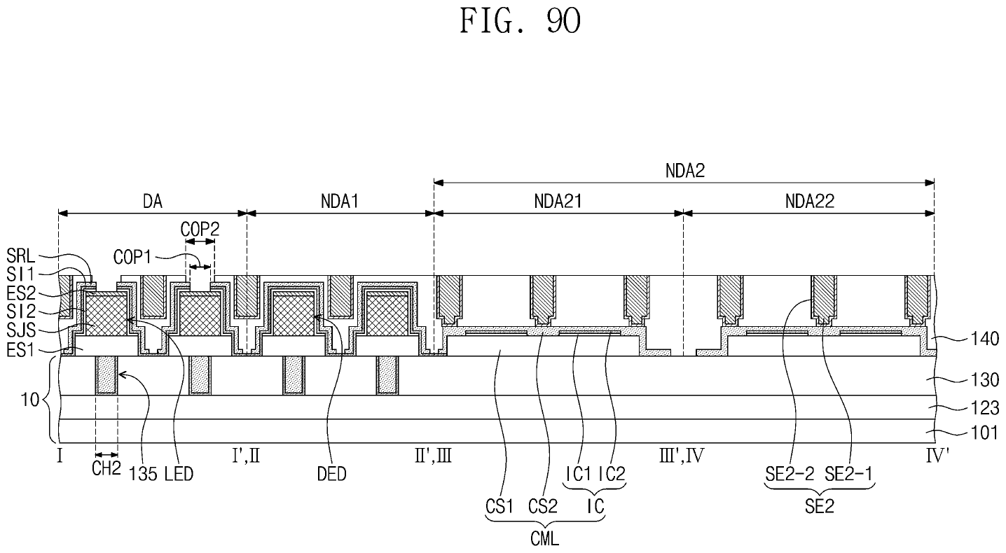

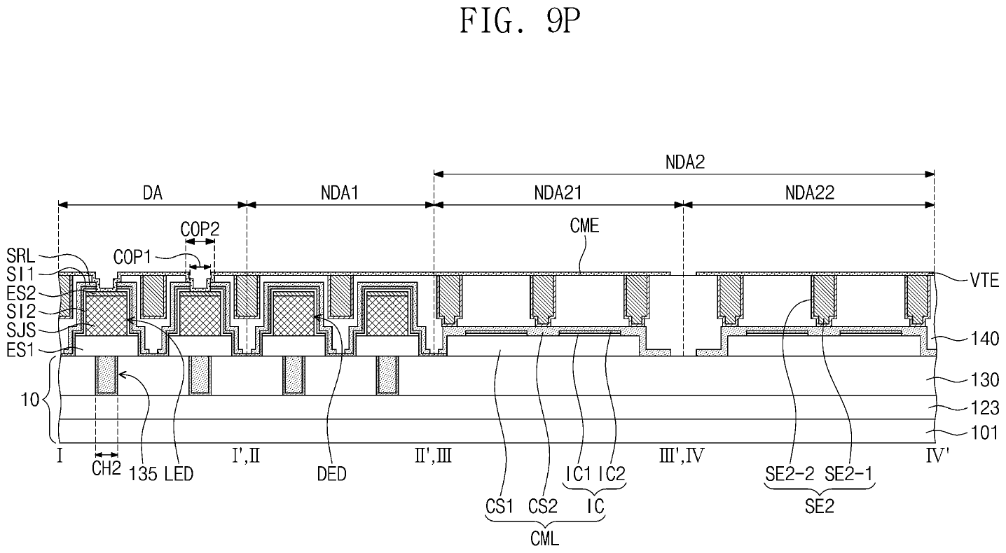

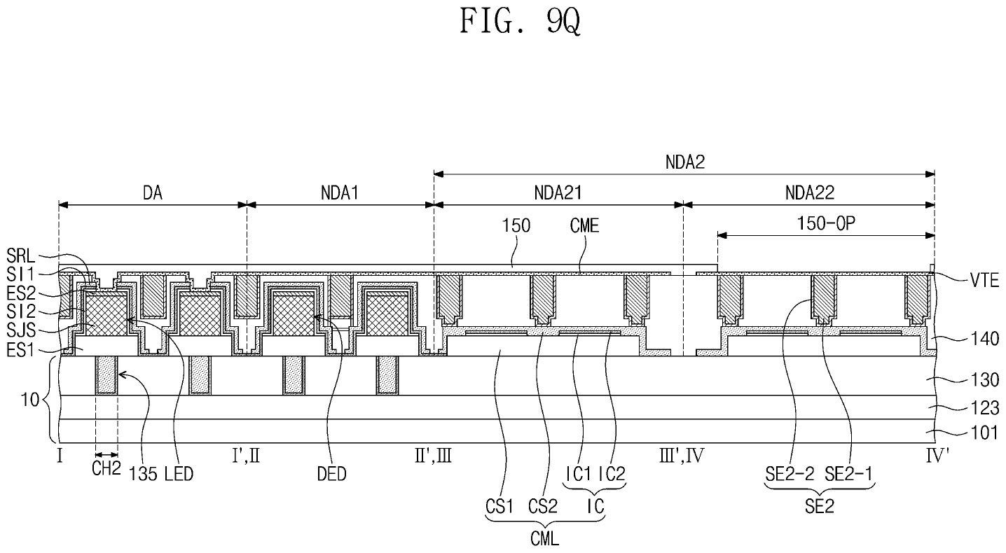

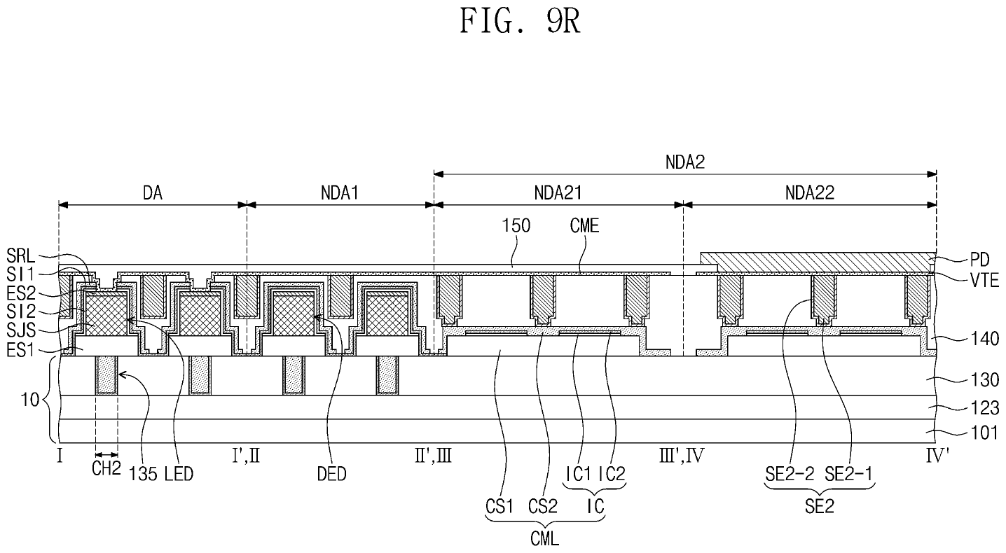

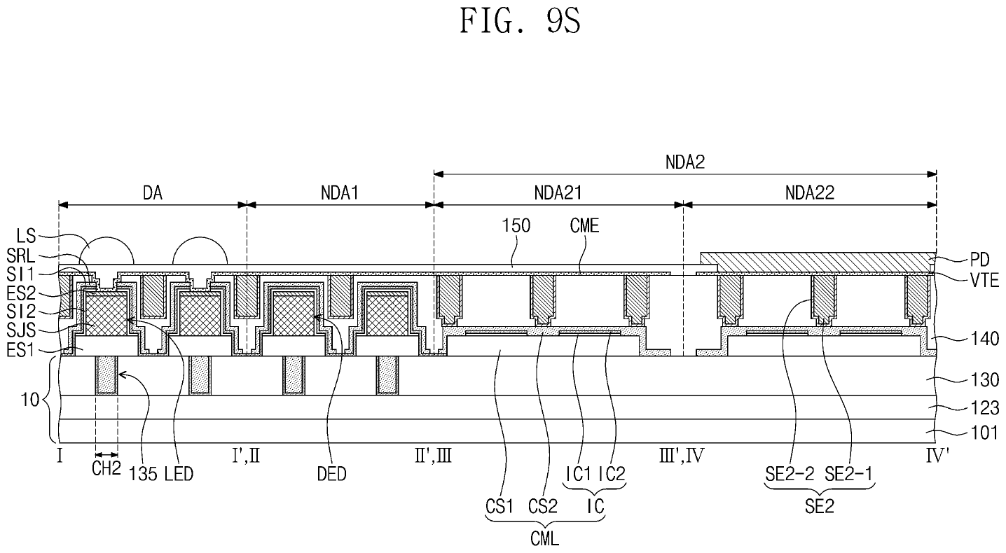

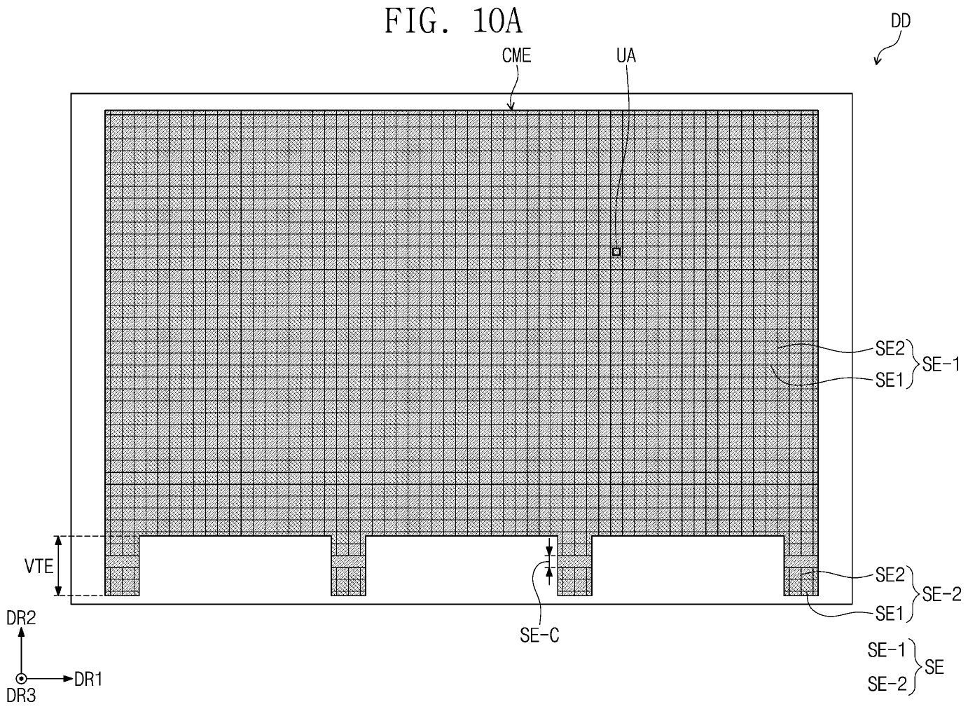

FIG. 9A is a schematic cross-sectional view illustrating a process of manufacturing the display device according to an embodiment. In FIGS. 9A to 9S, FIGS. 4B, 5B, 6B, and 7B are sequentially illustrated in one drawing, but the first area DA, the second area NDA1, the third-1 area NDA21, and third-2 area NDA22 may be intermittent.

As illustrated in FIG. 9A, a CMOS wafer 10 may be provided. The CMOS wafer 10 may include a silicon substrate 101, a first insulating layer 123, and a second insulating layer 130. The CMOS wafer 10 in FIG. 9A is illustrated to be simpler than the CMOS wafer 10 in FIG. 4B except for the second contact electrode 135. The second contact electrode 135 disposed in the second contact hole CH2 may be formed by a damascene process. The process of manufacturing the CMOS wafer 10 is not limited.

As illustrated in FIG. 9A, the first conductive layer CL1 may be disposed on the second insulating layer 130 of the CMOS wafer 10. The first conductive layer CL1 may be formed by a deposition process, and the type of deposition process used to form the first conductive layer CL1 is not limited. The first conductive layer CL1 may include at least one metal layer. The first conductive layer CL1 may include the first metal layer ML1 of FIG. 4E or the first and second metal layers ML1 and ML2. The first conductive layer CL1 may further include a barrier layer disposed below the at least one metal layer. The barrier layer may be the third barrier layer BRL3 in FIG. 4E or the third barrier layer BRL30 in FIG. 4F.

In an embodiment, a structure in which the first conductive layer CL1 includes the third barrier layer BRL3 of FIG. 4E and the first and second metal layers ML1 and ML2 disposed on the third barrier layer BRL3 will be described.

Next, as illustrated in FIG. 9B, a semiconductor substrate SUB-S may be provided. FIG. 9B illustrates the semiconductor substrate SUB-S aligned on the CMOS wafer 10.

The semiconductor substrate SUB-S may include a silicon substrate 201, a buffer layer 202 disposed below the silicon substrate 201, a semiconductor junction layer 203 disposed below the buffer layer 202, and a second conductive layer CL2 disposed the semiconductor junction layer 203. The buffer layer 202 may be an epitaxial layer grown from the silicon substrate 201.

The semiconductor junction layer 203 may include an active layer ACT, a p-type semiconductor layer SP disposed at a side of the active layer ACT, and an n-type semiconductor layer SN disposed at another side of the active layer ACT. In an embodiment, the semiconductor junction layer 203 may have the same laminated structure as the semiconductor junction member SJS described with reference to FIG. 4G. For example, the semiconductor junction layer 203 may include an n-type semiconductor layer SN, an active layer ACT disposed below the n-type semiconductor layer SN, and a p-type semiconductor layer SP disposed below the active layer ACT. The n-type semiconductor layer SN may have a thickness greater than that of the n-type semiconductor layer SN illustrated in FIG. 4G. This is because a portion is removed during a grinding process, as will be described later.

The second conductive layer CL2 may include a transparent conductive oxide layer, a reflective layer disposed below the transparent conductive oxide layer, and at least one metal layer disposed above the reflective layer. The second conductive layer CL2 may include at least one or more of the first transparent conductive oxide layer TCO1, the reflective layer RL, and the second and third metal layers ML2 and ML3 of FIG. 4E. The second conductive layer CL2 may include the third metal layer ML3 or may include the second and third metal layers ML2 and ML3.

The second conductive layer CL2 may further include a barrier layer. The barrier layer may include the first barrier layer BRL1 of FIG. 4E or the first barrier layer BRL10 of FIG. 4F. The barrier layer may further include the second barrier layer BRL2 of FIG. 4E or may include only the second barrier layer BRL2 of FIG. 4E.

In an embodiment, a structure in which the second conductive layer CL2 includes the first transparent conductive oxide layer TCO1 of FIG. 4E, the second barrier layer BRL2 disposed below the first transparent conductive oxide layer TCO1, the reflective layer RL disposed below the second barrier layer BRL2, the first barrier layer BRL1 disposed below the reflective layer RL, and the third metal layer ML3 disposed below the first barrier layer BRL1 will be described.

Next, as illustrated in FIG. 9C, the semiconductor substrate SUB-S may be coupled to the CMOS wafer 10. The second conductive layer CL2 may adhere to the first conductive layer CL1 through a high temperature and high pressure process. In an embodiment, the second metal layer ML2 of FIG. 4E and the third metal layer ML3 of FIG. 4E may adhere to each other. Thus, a first electrode layer ESL1 having the same laminated structure as the first electrode member ES1 described in FIG. 4E may be formed. In FIG. 9D, the first electrode layer ESL1 is illustrated as a single layer.

According to an embodiment, the uppermost metal layer of the first conductive layer CL1 and the lowermost metal layer of the second conductive layer CL2 may include the same metal, and the uppermost metal layer and the lowermost metal layer may be formed as a single metal layer after the adhesion process of the first conductive layer CL1 and the second conductive layer CL2. For example, the second metal layer ML2 in FIG. 4E may be a single metal layer formed after the adhesion process. The first conductive layer CL1 in FIG. 7C may include the third barrier layer BRL3 in FIG. 4E, the first metal layer ML1 on the third barrier layer BRL3, and the uppermost layer disposed on the first metal layer ML1, and the second conductive layer CL2 in FIG. 7C may include the first transparent conductive oxide layer TCO1 in FIG. 4E, the second barrier layer BRL2 below the first transparent conductive oxide layer TCO1, the reflective layer RL below the second barrier layer BRL2, the reflective layer RL below the second barrier layer BRL2, the first barrier layer BRL1 below the reflective layer RL, the third metal layer ML3 below the first barrier layer BRL1, and the lowest metal layer disposed below the third metal layer ML3. Through the coupling process of FIG. 9C, the uppermost metal layer of the first conductive layer CL1 and the lowermost metal layer of the second conductive layer CL2 may form a single metal layer, e.g., the second metal layer ML2 of FIG. 4E. As described above, the uppermost metal layer of the first conductive layer CL1 and the lowermost metal layer of the second conductive layer CL2 may include the same metal. Each of the uppermost metal layer of the first conductive layer CL1 and the lowermost metal layer of the second conductive layer CL2 may include any one of gold (Au), copper (Cu), silver (Ag), tin (SN), titanium (Ti), zirconium (Zr), and tantalum (Ta).

A method for forming the first electrode layer ESL1 having the same structure as the first electrode member ES1 of FIG. 4F will be described as follows. The first conductive layer CL1 in FIGS. 9A to 9C may include the third barrier layer BRL30 in FIG. 4F and the first metal layer on the third barrier layer BRL30. The second conductive layer CL2 in FIGS. 9B and 9C may include the first transparent conductive oxide layer TCO1 of FIG. 4E, the second barrier layer BRL2 disposed below the first transparent conductive oxide layer TCO1, the reflective layer RL disposed below the second barrier layer BRL2, the first barrier layer BRL10 disposed below the reflective layer RL, and the second metal layer disposed below the first barrier layer BRL10.

In case that the first conductive layer CL1 and the second conductive layer CL2 are coupled as illustrated in FIG. 9C, a first electrode layer ESL1 having the same laminated structure as the first electrode member ES1 in FIG. 4F may be formed. In case that the first metal layer and the second metal layer include the same metal, a single-layer metal layer ML including a single metal may be formed as illustrated in FIG. 4F. In case that the first metal layer and the second metal layer include different metals, the metal of the first metal layer and the metal of the second metal layer may be diffused into each other to form an alloy layer.

Next, as illustrated in FIG. 9D, a portion of the semiconductor substrate SUB-S of FIG. 9C may be removed to form a semiconductor junction structure layer SJSL. The grinding process for the semiconductors may be performed. The silicon substrate 201 and buffer layer 202 of FIG. 9C may be removed (e.g., completely removed), and a portion of the semiconductor junction layer 203 may be removed. FIG. 9D illustrates the semiconductor junction structure layer SJSL formed by removing a portion of the semiconductor junction layer 203.

The semiconductor junction structure layer SJSL may have the same laminated structure as the semiconductor junction member SJS of FIG. 4F. Corresponding layers of the semiconductor junction structure layer SJSL and the semiconductor junction member SJS may have the same thickness.

For example, both the semiconductor junction structure layer SJSL and the first electrode layer ESL1 may be removed from a partial area (hereinafter, referred to as an align key area) that is not illustrated. An align key formed on the CMOS wafer 10 may be exposed to the outside through the align key area. The align key may be used in a photolithography process performed in a subsequent process.

Next, as illustrated in FIG. 9E, the second electrode layer ESL2 may be formed on the semiconductor junction structure layer SJSL. The second electrode layer ESL2 may have the same laminated structure as the second electrode member ES2 described in FIG. 4G. A transparent conductive oxide layer of the second electrode layer ESL2 may be formed by a deposition process. The second electrode layer ESL2 may further include a metal layer disposed below the transparent conductive oxide layer. The metal layer that is in contact with the semiconductor junction structure layer SJSL may be formed by a primary deposition process. A transparent conductive oxide layer may be formed (e.g., directly formed) on the metal layer by a secondary deposition process.

According to an embodiment, the second electrode layer ESL2 may be formed in advance between the buffer layer 202 and the semiconductor junction layer 203. For example, a process of removing a portion of the semiconductor junction layer 203 of FIG. 9D may not be performed, and only the silicon substrate 201 and the buffer layer 202 may be removed.

Next, as illustrated in FIG. 9F, the semiconductor junction structure layer SJSL and the second electrode layer ESL2 may be patterned. After forming a hard mask MSK by a photolithography process, the semiconductor junction structure layer SJSL and the second electrode layer ESL2 of FIG. 9E may be etched using the hard mask MSK. The hard mask MSK may include an insulating pattern. Semiconductor junction members SJS overlapping the first area DA and the second area NDA1 may be formed from the semiconductor junction structure layer SJSL of FIG. 9E. Second electrode members ES2 overlapping the semiconductor junction members SJS may be formed from the second electrode layer ESL2 of FIG. 9E. The semiconductor junction structure layer SJSL and the second electrode layer ESL2 may be removed from the third area NDA2.

During the etching process, side surfaces of the semiconductor junction members SJS and the second electrode members ES2 may be damaged. However, the damage of the side surfaces of the semiconductor junction members SJS and the second electrode members ES2 may be repaired by a wet treatment process.

Next, as illustrated in FIG. 9G, the hard mask MSK of FIG. 9F may be removed, and a first insulating layer SI-1 may be formed on the CMOS wafer 10. The first insulating layer SI-1 may be an inorganic layer and may be formed by a process of depositing an inorganic material. The first insulating layer SI-1 may be disposed on the first electrode layer ESL1, may surround the side surfaces of the semiconductor junction members SJS and the second electrode members ES2, and may be disposed on top surfaces (or upper surfaces) of the second electrode members ES2.

Next, as illustrated in FIG. 9H, the first insulating layer SI-1 and the first electrode layer ESL1 may be patterned. Thus, light emitting diodes LED overlapping in the first area DA and dummy light emitting diodes DED overlapping in the second area NDA1 may be formed.

A photolithography process may be performed for the patterning. The second side insulating layer SI2 described with reference to FIG. 4B may be formed from the first insulating layer SI-1, and the first electrode members ES1 overlapping the first area DA and the second area NDA1 may be formed from the first electrode layer ESL1. In case that a process of forming the first insulating layer SI-1 in FIG. 9G is omitted, the second side insulating layer SI2 may not be formed.

A first conductive member CS1 overlapping the third area NDA2 may be formed from the first electrode layer ESL1. The first conductive member CS1 may have the same laminated structure as the first electrode member ES1 as described with reference to FIGS. 6B and 7B. A first insulating pattern layer IC1 disposed on the first conductive member CS1 may be formed from the first insulating layer SI-1 in FIG. 9G. The first insulating pattern layer IC1 may cover the top surface (or upper surface) of the first conductive member CS1.

Due to a process error between the photolithography process of FIG. 9H and the etching process using the hard mask MSK of FIG. 9F, the first electrode members ES1 having an area greater than that of the second electrode members ES2 may be formed. In the photolithography process of FIG. 9H, the second side insulating layer SI2 may be protected by a photoresist. The first electrode members ES1 may be formed to have a larger area so as to protect the second side insulating layer SI2 and the side surfaces of the semiconductor junction members SJS protected by the second side insulating layer SI2. Thus, the second side insulating layer SI2 may be disposed on a partial area of the top surface (or upper surface) of the first electrode members ES1.

Next, as illustrated in FIG. 9I, a second insulating layer SI-2 may be formed on the CMOS wafer 10. The second insulating layer SI-2 may be an inorganic layer and may be formed by a process of depositing an inorganic material.

The second insulating layer SI-2 may be disposed on the second side insulating layer SI2 to cover the side surfaces of the first electrode members ES1. The second insulating layer SI-2 may cover the side surface of the first conductive member CS1 and may be disposed on the first insulating pattern layer IC1. The second insulating layer SI-2 may be disposed on a partial area of the top surface (or upper surface) of the CMOS wafer 10.

Next, as illustrated in FIG. 9J, the second insulating layer SI-2 may be patterned. The process in FIGS. 9I and 9J may be performed during a photolithography process.

The first side insulating layer SI1 of FIG. 9J may be formed from the second insulating layer SI-2 of FIG. 9I. Although the first side insulating layer SI1 is illustrated to have an integrated shape on the first area DA and the second area NDA1, first side insulating layers SI1, which are separated from each other, may be formed on each of the light emitting diodes LED and the dummy light emitting diodes DED.

A second insulating pattern layer IC2 may be disposed on a first insulating pattern layer IC1 on the third area NDA2. The laminated structure of the first insulating pattern layer IC1 and the second insulating pattern layer IC2 may be defined as the insulating member IC of FIGS. 6B and 7B. An opening IC-OP exposing the top surface (or upper surface) of the first conductive member CS1 may be defined in the insulating member IC. The shape of the opening IC-OP is not limited. As illustrated in FIG. 9J, both edges of the first conductive member CS1 may also be exposed from the insulating member IC.

Next, as illustrated in FIG. 9K, a metal layer ML-R may be formed on the CMOS wafer 10. A metal layer ML-R may be formed by a deposition process. The metal layer ML-R may be formed to overlap the first area DA, the second area NDA1, and the third area NDA2. The metal layer ML-R may include gold (Au), copper (Cu), silver (Ag), titanium (Ti), or aluminum (Al).

As illustrated in FIG. 9L, the side reflection layer SRL and the second conductive member CS2 may be formed from the metal layer ML-R by the photolithography process.

The side reflective layer SRL may be formed to overlap the first area DA and the second area NDA1. The side reflective layer SRL may be disposed outside the first side insulating layer SI1 and may be in contact with the first side insulating layer SI1. Although side reflective layers SRL are illustrated disposed on each of the second side insulating layers SI2, in an embodiment, the side reflective layers SRL may have an integrated shape in the first area DA and the second area NDA1.

In case that patterning the conductive layer ML-R, the first opening COP1 may be formed. The first opening COP1 may pass through the first side insulating layer SI1, the second side insulating layer SI2, and the side reflective layer SRL of the light emitting diode LED to expose a partial area of the top surface (or upper surface) of the second electrode member ES2. The first opening COP1 may not be formed in the dummy light emitting diode DED. In the wet etching process of forming the first opening COP1, the transparent conductive oxide of the second electrode member ES2 may protect the semiconductor junction member SJS, which is disposed therebelow, from an etchant.

The second conductive member CS2 may be formed to overlap the third area NDA2. The second conductive member CS2 may be disposed on the first conductive member CS1 and the insulating member IC, and may be in contact with a partial area of the first conductive member CS1 exposed from the insulating member IC. The second conductive member CS2 may be connected to the first conductive member CS1 at least through the opening IC-OP. The laminated structure of the first conductive member CS1, the insulating member IC, and the second conductive member CS2 may be defined as the common line CML described with reference to FIGS. 6B and 7B.

As illustrated in FIG. 9M, a planarization layer 140, in which the second trench TC2 is defined, is formed. The planarization layer 140 provided as an organic layer may be formed on the CMOS wafer 10 by an inkjet process or a coating process. Thereafter, a second trench TC2 may be formed in the planarization layer 140 by a first photolithography process. For example, in case of forming the second trench TC2, the first trench TC1 illustrated in FIGS. 4A, 5A, 6A, and 7A may also be formed.

A through-hole TH extending from the second trench TC2 may be further formed by a secondary photolithography process. The through-hole TH may be formed in an area overlapping the common line CML of the third area NDA2.

In an embodiment, in case that the second trench TC2 is formed deeper by the first photolithography process, the second trench TC2 illustrated in FIGS. 8A and 8B may be formed, and the secondary photolithography process of forming the through-hole TH of FIG. 9M may be omitted.

As illustrated in FIG. 9N, a second auxiliary electrode SE2 may be formed in the second trench TC2. In case of forming the second auxiliary electrode SE2, the first auxiliary electrode SE1 illustrated in FIGS. 4A, 5A, 6A, and 7A may also be formed.

The second auxiliary electrode SE2 may be formed using a damascene method. After forming a thin barrier layer on the planarization layer 140 by a first deposition process, a metal layer may be formed to be thicker than the barrier layer by a second deposition process. The metal layer having stepped portions may be formed on the second trenches TC2 and the surrounding area. The barrier layer and metal layer disposed on the planarization layer 140 may be removed by a chemical mechanical polishing (CMP) process. Thus, the second auxiliary electrode SE2 including the barrier layer SE2-2 and the metal member SE2-1, which are disposed only inside the second trench TC2, may be formed.

Thereafter, as illustrated in FIG. 9O, a second opening COP2 may be formed in the planarization layer 140. The second openings COP2 may be formed to correspond to the first openings COP1, and the second electrode member ES2 may be exposed to the outside. The second electrode member ES2 of the dummy light emitting diode DED may not be exposed to the outside. The second openings COP2 having a diameter greater than that of the first openings COP1 are illustrated as examples, but embodiments are not limited thereto.

Next, as illustrated in FIG. 9P, a common electrode CME may be formed on the planarization layer 140 to overlap the first area DA, the second area NDA1, and the third-1 area NDA21. A voltage transmission electrode VTE may be formed on the planarization layer 140 to overlap the third-2 area NDA22.

The common electrode CME and the voltage transmission electrode VTE, which have an integrated shape, may be formed by the photolithography process. The common electrode CME may be electrically connected to the light emitting diode LED through the first opening COP1 and the second opening COP2. A transparent conductive oxide layer may be formed on the planarization layer 140 by the deposition process and patterned to form the common electrode CME and the voltage transmission electrode VTE having the shape illustrated in FIG. 3A.

Next, as illustrated in FIG. 9Q, a passivation layer 150 covering the common electrode CME may be formed on the planarization layer 140. The passivation layer 150 covers the voltage transmission electrode VTE, and an opening 150-OP may be formed in the passivation layer 150 to expose a connection area of the voltage transmission electrode VTE.

Thereafter, as illustrated in FIG. 9R, a pad electrode PD connected to the connection area of the voltage transmission electrode VTE may be formed on the planarization layer 140. The pad electrode PD may be connected to the connection area of the voltage transmission electrode VTE through the opening 150-OP.

For example, as illustrated in FIG. 9S, lenses LS may be formed on the planarization layer 140 to overlap the light emitting diodes LEDs. The lenses LS may be formed by patterning an organic layer by the photolithography process, or the lenses LS may be formed by dropping and drying the organic material by an inkjet process.

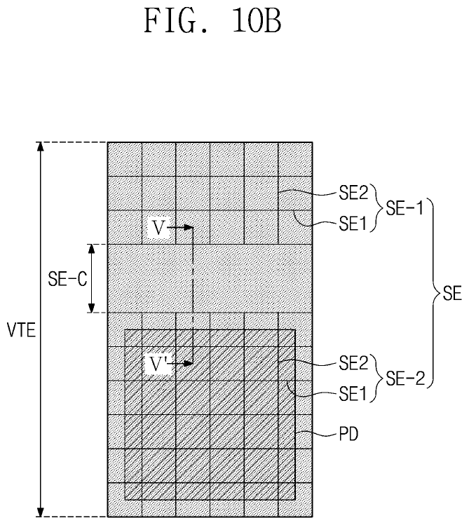

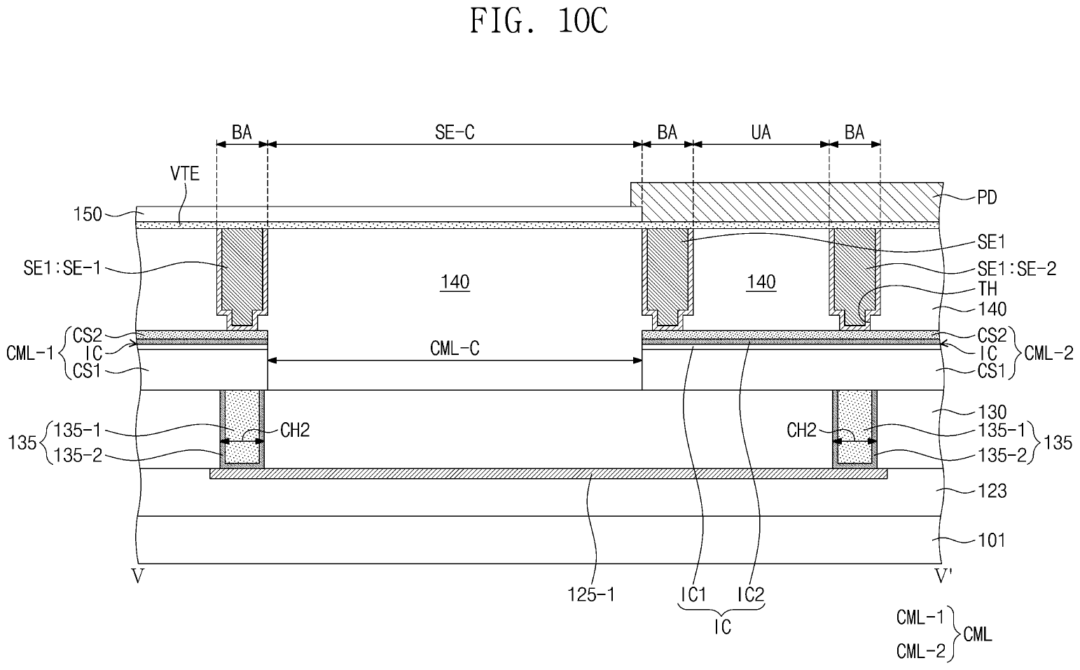

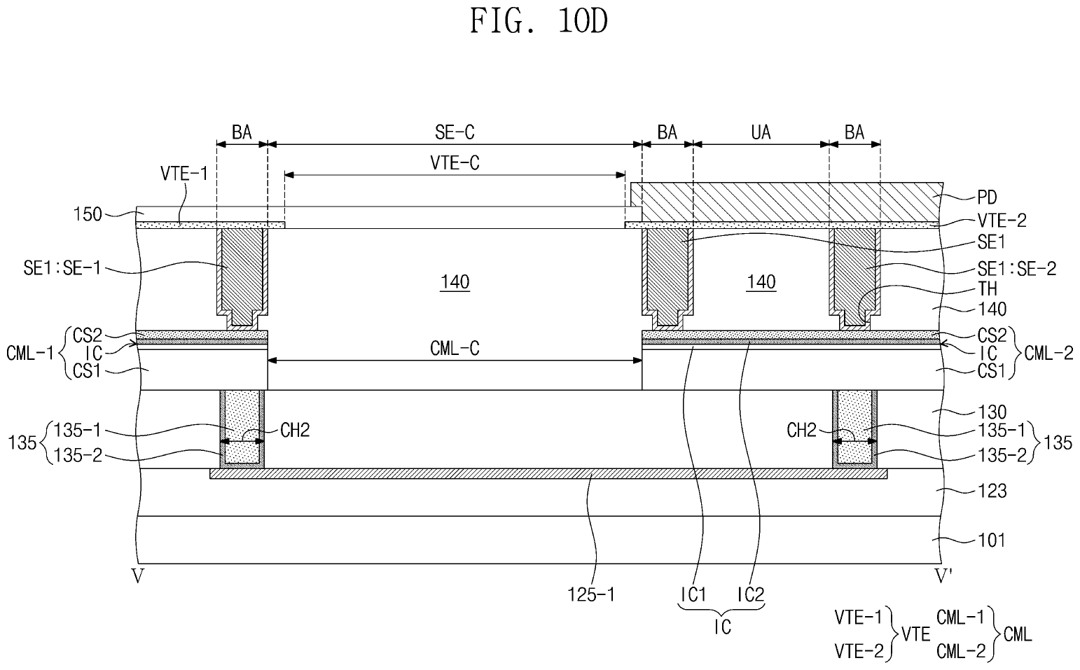

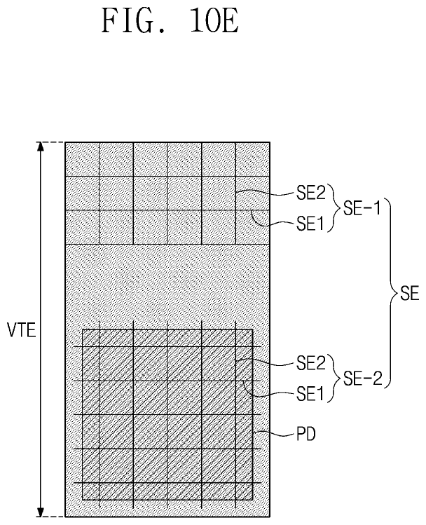

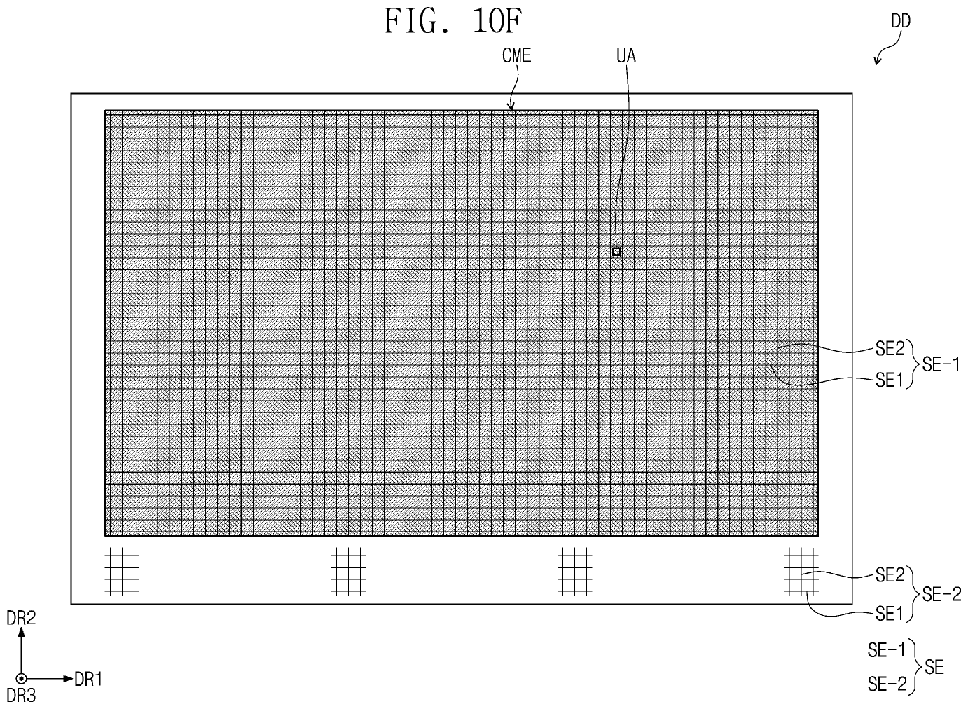

FIG. 10A is a schematic plan view illustrating an arrangement relationship between the common electrode CME, the voltage transmission electrode VTE, and the auxiliary electrode SE according to an embodiment. FIG. 10B is an enlarged schematic plan view illustrating a partial area of the third-2 area NDA22 according to an embodiment. FIGS. 10C and 10D are schematic cross-sectional views taken along line V-V′ of FIG. 10B. FIG. 10E is an enlarged schematic plan view illustrating a partial area of the third-2 area NDA21 according to an embodiment. FIG. 10F is a schematic plan view illustrating an arrangement relationship between the common electrode CME and the auxiliary electrode SE according to an embodiment.

FIG. 10A may correspond to FIG. 3B. According to FIG. 10A, the auxiliary electrode SE may include a cut area SE-C. In an embodiment, some of the second auxiliary electrodes SE2 are illustrated as being cut. The cut area SE-C of the auxiliary electrode SE may overlap the voltage transmission electrode VTE.

The auxiliary electrode SE may include a first portion SE-1 overlapping the common electrode CME and a second portion SE-2 overlapping the voltage transmission electrode VTE and the pad electrode PD of FIG. 3A. The pad electrode PD of FIG. 3A may not overlap the first portion SE-1. The first portion SE-1 and the second portion SE-2 may be spaced apart from each other on a plane (e.g., a plan view).

FIG. 10B is an enlarged schematic view of a distal area of the voltage transmission electrode VTE of FIG. 10A. The pad electrode PD overlapping the second portion SE-2 is illustrated. As described above, the first portion SE-1 of the auxiliary electrode SE and the second portion SE-2 of the auxiliary electrode SE may be disposed to be spaced apart from each other. An edge portion (or end portion) of the second portion SE-2 of the auxiliary electrode SE is illustrated to be aligned in a plan view with the edge portion of the voltage transmission electrode VTE, but embodiments are not limited thereto.

Referring to FIG. 10C, a cut area CML-C may also be defined in the common line CML. The cut area CML-C of the common line CML may be defined substantially the same as the cut area SE-C of the auxiliary electrode SE, but embodiments are not limited thereto. The common line CML may include a first common portion CML-1 and a second common portion CML-2, which is spaced apart from the first common portion CML-1. The first common portion CML-1 of the common line CML may be disposed below the first portion SE-1 of the auxiliary electrode SE and may be electrically connected to the first portion SE-1 of the auxiliary electrode SE. The second common portion CML-2 of the common line CML may be disposed below the second portion SE-2 of the auxiliary electrode SE and may be electrically connected to the second portion SE-2 of the auxiliary electrode SE.

Second contact electrodes 135 and a connection electrode 125-1 may be disposed to electrically connect the pad electrode PD to the common electrode CME. The connection electrode 125-1 may be formed by the same process, by which the first contact electrode 125 of FIG. 4B is formed, and may include the same laminated structure and the same material. The connection electrode 125-1 may overlap the cut area SE-C of the auxiliary electrode SE to replace functions of the cut auxiliary electrode SE and the cut common line CML. For example, a power voltage applied through the pad electrode PD may pass through the connection electrode 125-1 and be transmitted to the common electrode CME of FIG. 10A. Referring to FIG. 10C, the power voltage may be transmitted in parallel to the common electrode CME of FIG. 10A through the voltage transmission electrode VTE.

Referring to FIG. 10D, the voltage transmission electrode VTE may include a first portion VTE-1, a second portion VTE-2, and a cut area VTE-C defined corresponding to the cut area SE-C of the auxiliary electrode SE. Widths and lengths of the cut area SE-C of the auxiliary electrode SE and the cut area VTE-C of the voltage transmission electrode VTE are not limited to being the same. For example, the pad electrode PD and the common electrode CME may be electrically connected only through a passage defined by the second contact electrodes 135 and the connection electrode 125-1. In an embodiment, the first portion VTE-1 of the voltage transmission electrode VTE may be omitted. The second portion SE-2 of the voltage transmission electrode VTE may correspond to the first conductive layer of the pad electrode PD.

Referring to FIG. 10E, an edge portion (or end portion) of the second portion SE-2 of the auxiliary electrode SE may not be aligned with the edge portion of the voltage transmission electrode VTE in a plan view. The second portion SE-2 of the first auxiliary electrode SE1 and the distal end portion of the second portion SE-2 of the second auxiliary electrode SE2 may be disposed inside the voltage transmission electrode VTE in a plan view.

Referring to FIG. 10F, as compared to the display device described with reference to FIGS. 10A to 10D, the voltage transmission electrode VTE may be omitted. Since the voltage transmission electrode VTE is omitted, the first portion SE-1 and the second portion SE-2 in FIG. 10C may be electrically connected to each other only the passage defined by the second contact electrodes 135 and the connection electrode 125-1.

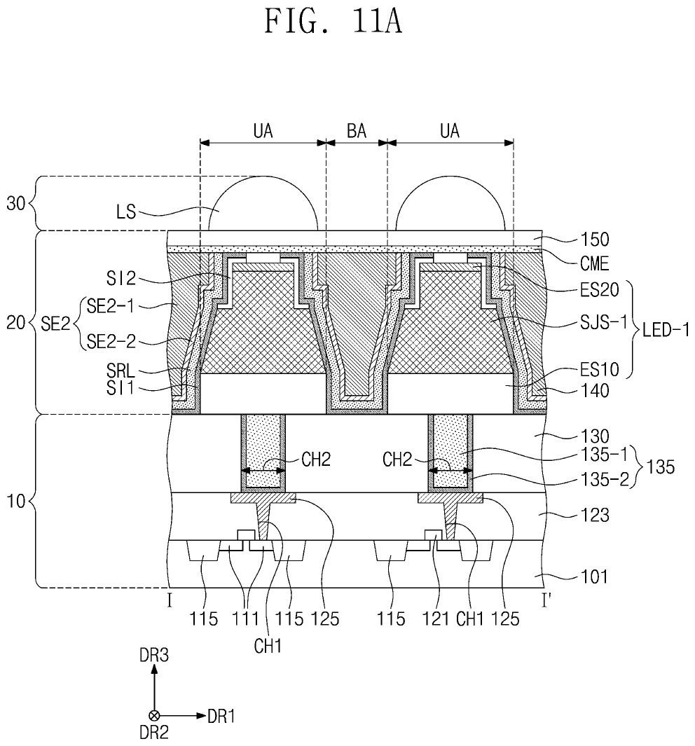

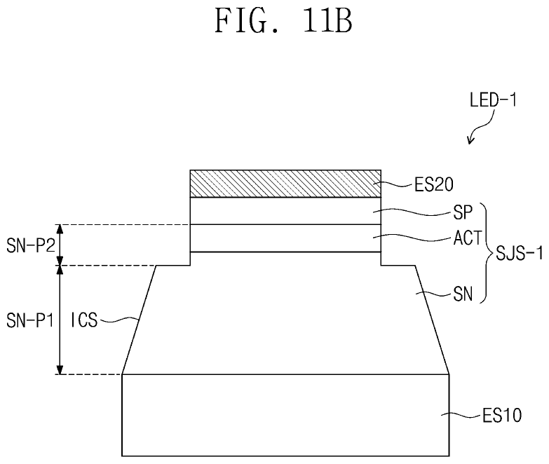

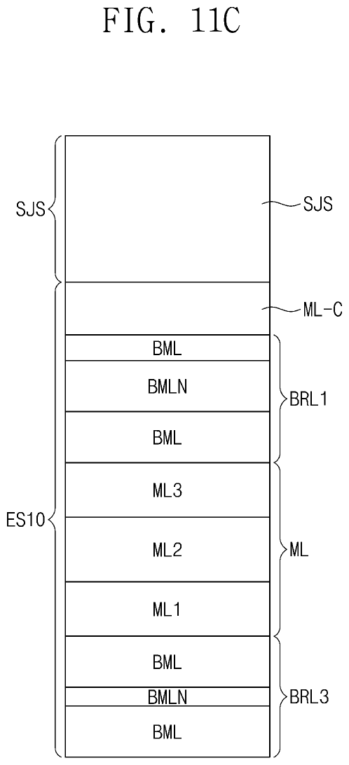

FIG. 11A is a schematic cross-sectional view illustrating a display device according to an embodiment. FIG. 11B is a schematic cross-sectional view illustrating a light emitting diode LED-1 according to an embodiment. FIG. 11C is a schematic cross-sectional view illustrating a first electrode member ES10 according to an embodiment.

FIG. 11A may correspond to FIG. 4B, and the same reference numerals are used for the same components among the components illustrated in FIGS. 4B and 11A. Hereinafter, description will focus on different configurations among those illustrated in FIGS. 4B and 11A.

In FIG. 11A, the light emitting diode LED-1 having an inverted structure may be applied. In an embodiment, the first electrode member ES10 is described as a cathode (or cathode member), and the second electrode member ES20 is described as an anode (or anode member).

As illustrated in FIG. 11B, a semiconductor junction member SJS-1 may be disposed on the first electrode member ES10, and the first electrode member ES10 may be disposed on a semiconductor junction member SJS-1. The semiconductor junction member SJS-1 may include an n-type semiconductor layer SN disposed on the first electrode member ES10, an active layer ACT disposed on the n-type semiconductor layer SN, and a p-type semiconductor layer SP disposed on the active layer ACT. In an embodiment, an electron blocking layer may be further disposed between the active layer ACT and the p-type semiconductor layer SP. In an embodiment, the light emitting diode LED-1 may further include a clad layer or a tensile strain barrier reducing (TSBR) layer.

The n-type semiconductor layer SN may include a first portion SN-P1 having a larger diameter (or horizontal length in cross section) and disposed closer to the first electrode member ES10 and a second portion SN-P2 having a smaller diameter (or horizontal length in cross section) and disposed farther from the first electrode member ES10. A stepped portion may be formed between the first portion SN-P1 and the second portion SN-P2. A side surface of the first portion SN-P1 may be an inclined surface ICS inclined to the first electrode member ES10, and a side surface of the second portion SN-P2 may be substantially perpendicular to the first electrode member ES10.

The second electrode member ES20 may include a transparent conductive oxide layer. The second electrode member ES20 may include at least one of indium tin oxide (ITO), indium zinc oxide (IZO), zinc oxide (ZnO), zinc tin oxide (ZTO), and indium gallium zinc oxide (IGZO).

The first electrode member ES10 may have the laminated structure illustrated in FIG. 11C. As compared to the laminated structure of FIG. 4E, the first transparent conductive oxide layer TCO1 and the second barrier layer BRL2 may be omitted. The first electrode member ES10 may include a metal layer ML-C disposed on the first barrier layer BRL1. The metal layer ML-C may have a function of the reflection layer RL and a function of the electron injection layer in FIG. 4E. The metal layer ML-C may have a multi-layer structure and may include a first metal layer corresponding to a reflective layer. The metal layer ML-C may further include a second metal layer having a work function less than that of the reflective layer. The metal layer ML-C may include a magnesium alloy or an aluminum alloy. In an embodiment, in the first electrode member ES10, the first transparent conductive oxide layer TCO1 and the second barrier layer BRL2 may be omitted compared to the laminated structure of FIG. 4F. For example, the metal layer ML-C described above may be disposed by replacing the reflective layer RL.

Referring again to FIG. 11A, the second side insulating layer SI2 may be in contact with a portion of each of the side surface of the semiconductor junction member SJS-1 and the side surface of the second electrode member ES20. The second side insulating layer SI2 may be in contact with the side surfaces of the p-type semiconductor layer SP, the active layer ACT, and the second portion SN-P2, and the second side insulating layer SI2 may expose the inclined surface ICS described in FIG. 11B. The second side insulating layer SI2 may be further disposed on a portion of a top surface (or upper surface) of the second electrode member ES20.

The first side insulating layer SI1 may be disposed outside the second side insulating layer SI2. The first side insulating layer SI1 may be in contact with the inclined surface ICS. The first opening COP1 may be defined (or formed) in the first side insulating layer SI1 and the second side insulating layer SI2.

A side reflective layer SRL may be disposed outside the first side insulating layer SI1. In an embodiment, the side reflection layer SRL is illustrated as being continuously disposed on adjacent light emitting diodes LED-1, but embodiments are not limited thereto. As illustrated in FIG. 4B, the side reflective layer SRL may be separated from and spaced apart from the boundary area BA. In an embodiment, the side reflective layer SRL may not be disposed on the top surface (or upper surface) of the second electrode member ES20, unlike the first side insulating layer SI1, but embodiments are not limited thereto.

According to an embodiment, unlike FIG. 4E, the planarization layer 140 is omitted. The boundary area BA may be defined by the light emitting diodes LED-1. An area on which the light emitting diodes LED-1 are not arranged or the spaced area may correspond to the boundary area BA. For example, in case that the light emitting diodes LED-1 are arranged in the form of a matrix, the boundary area BA between the light emitting diodes LED-1 may have a grid shape in a plan view. In FIG. 11A, the boundary area BA is illustrated based on the side surface of the first electrode member ES10.

The auxiliary electrode SE disposed on the boundary area BA may have a grid shape as illustrated in FIG. 3B. In FIG. 11A, second auxiliary electrodes SE2, which are portions of the auxiliary electrode SE, are illustrated. The second auxiliary electrodes SE2 may include a metal member SE2-1 and a barrier layer SE2-2 disposed between the metal member SE2-1 and the second trench TC2. Since the second auxiliary electrodes SE2 are not formed in the second trench TC2 of FIG. 4B, but are disposed on the area between the light emitting diodes LED-1, the second auxiliary electrodes SE2 may have different widths according to an area in cross section.

During the manufacturing process, a planarization process such as a grinding process may be performed, and thus the side reflective layer SRL and the auxiliary electrode SE may provide a flat top surface. A portion of the first side insulating layer SI1 may also be removed during the planarization process. The common electrode CME may be disposed on the top surface provided by the side reflection layer SRL and the auxiliary electrode SE and may be electrically connected to the second electrode member ES20 through the first opening COP1.

According to the above, the first electrode member (e.g., ES1 or ES10) with the reduced defects may be provided. The first electrode member (e.g., ES1 or ES10) may be provided by the coupling process of the CMOS wafer 10 and the semiconductor substrate SUB-S.

The side reflective layer SRL may reflect the light generated from the light emitting diode LED to improve the emission efficiency. The lens LS may concentrate the emitted light to reduce the light loss.

The auxiliary electrode SE disposed inside the trenches (e.g., TC1 or TC2) may be overall connected to the common electrode CME to reduce the voltage drop occurring in the common electrode CME.

In concluding the detailed description, those skilled in the art will appreciate that many variations and modifications may be made to the embodiments without substantially departing from the principles and spirit and scope of the disclosure. Therefore, the disclosed embodiments are used in a generic and descriptive sense only and not for purposes of limitation.

What is claimed is:

1. A display device comprising:
a complementary metal oxide semiconductor (CMOS) wafer; and
a plurality of light emitting diodes disposed on the CMOS wafer and disposed in a first area of the CMOS wafer in a plan view,
wherein each of the plurality of light emitting diodes comprises:
a first electrode member comprising:
a metal layer;
a reflective layer disposed on the metal layer; and
a first transparent conductive oxide layer disposed on the reflective layer;
an emission layer disposed on the first electrode member; and
a second electrode member disposed on the emission layer.

2. The display device of claim 1, wherein the metal layer comprises at least one of gold (Au), copper (Cu), silver (Ag), tin (SN), titanium (Ti), zirconium (Zr), and tantalum (Ta), or comprises an alloy of at least two metals of gold (Au), copper (Cu), silver (Ag), tin (SN), titanium (Ti), zirconium (Zr), and tantalum (Ta).

3. The display device of claim 1, wherein
the metal layer comprises a first metal layer and a second metal layer disposed on the first metal layer,
the first metal layer comprises at least one of gold (Au), copper (Cu), silver (Ag), tin (SN), titanium (Ti), zirconium (Zr), and tantalum (Ta), and
the second metal layer comprises another one of gold (Au), copper (Cu), silver (Ag), tin (SN), titanium (Ti), zirconium (Zr), and tantalum (Ta).

4. The display device of claim 3, wherein
the metal layer further comprises a third metal layer disposed on the second metal layer,
the third metal layer comprises at least one of gold (Au), copper (Cu), silver (Ag), tin (SN), titanium (Ti), zirconium (Zr), and tantalum (Ta), and
the third metal layer includes a metal different from the second metal layer.

5. The display device of claim 1, wherein
the first electrode member further comprises:
a first barrier layer disposed between the metal layer and the reflective layer; and
a second barrier layer disposed between the reflective layer and the first transparent conductive oxide layer, and
each of the first barrier layer and the second barrier layer comprises a nitride layer made of barrier metal nitride.

6. The display device of claim 5, wherein
the first barrier layer further comprises a barrier metal layer disposed at at least one side of upper and lower sides of the nitride layer made of the barrier metal nitride, and
the barrier metal layer comprises titanium (Ti) or tantalum (Ta).

7. The display device of claim 1, wherein
the first electrode member further comprises a barrier layer disposed below the metal layer, and
the barrier layer comprises titanium nitride or tantalum nitride.

8. The display device of claim 1, wherein the CMOS wafer comprises:
a silicon substrate in which a source region or a drain region is formed;
a gate electrode disposed on the silicon substrate;
a first insulating layer covering the gate electrode and disposed on the silicon substrate;
a first contact electrode electrically connected to the source region or the drain region through a first contact hole passing through the first insulating layer;
a second insulating layer covering the first contact electrode and disposed on the first insulating layer; and
a second contact electrode electrically connected to the first contact electrode through a second contact hole passing through the second insulating layer and electrically connected to the metal layer of the first electrode member.

9. The display device of claim 8, wherein
the second contact electrode comprises:
a metal member disposed inside the second contact hole; and
a barrier layer disposed between a side surface of the metal member and an inner surface of the second contact hole and disposed between a lower surface of the metal member and an upper surface of the first contact electrode exposed through the second contact hole, and
the barrier layer comprises a metal layer made of barrier metal and a nitride layer made of barrier metal nitride.

10. The display device of claim 8, wherein an upper surface of the second contact electrode is concave.

11. The display device of claim 1, wherein the second electrode member comprises a second transparent conductive oxide layer.

12. The display device of claim 11, wherein
the second electrode member is a cathode of each of the plurality of light emitting diodes, and
the second electrode member further comprises an electrode metal layer disposed between the second transparent conductive oxide layer and a semiconductor junction member.

13. The display device of claim 11, wherein
the second electrode member is an anode of each of the plurality of light emitting diodes,
the first electrode member is a cathode of each of the plurality of light emitting diodes,
the emission layer comprises:
an n-type semiconductor layer;
an active layer disposed on the n-type semiconductor layer; and
a p-type semiconductor layer disposed on the active layer,
the n-type semiconductor layer comprises a first portion and a second portion having a width less than that of the first portion in cross section, and
a side surface of the second portion is an inclined surface that is inclined with respect to the first electrode member.

14. The display device of claim 1, wherein, in a plan view, the emission layer is disposed inside the first electrode member.

15. The display device of claim 1, further comprising:
a first side insulating layer disposed on a side surface of the first electrode member, a side surface of the emission layer, a side surface of the second electrode member, and an upper surface of the second electrode member; and
a side reflective layer disposed outside the first side insulating layer.

16. The display device of claim 15, wherein the side reflective layer is adjacent to at least one of the side surface of the first electrode member, the side surface of the emission layer, and the side surface of the second electrode member.

17. The display device of claim 15, further comprising:
a second side insulating layer, wherein
a partial area of an upper surface of the first electrode member is exposed from the emission layer,
the second side insulating layer is disposed inside the first side insulating layer and corresponds to an upper surface of the first electrode member, the side surface of the emission layer, the side surface of the second electrode member, and an upper surface of the second electrode member, and
an opening through which the partial area of the upper surface of the second electrode member is exposed is formed in the side reflective layer, the first side insulating layer, and the second side insulating layer.

18. The display device of claim 17, further comprising:
a common electrode, wherein
the plurality of light emitting diodes comprise a first light emitting diode and a second light emitting diode,
the common electrode electrically connects the second electrode member of the first light emitting diode to the second electrode member of the second light emitting diode, and
the common electrode adheres to the partial area of the upper surface of the second electrode member through the opening.

19. The display device of claim 1, further comprising:
a planarization layer disposed on the CMOS wafer and adjacent to a side surface of the first electrode member and a side surface of the emission layer; and
a common electrode disposed on the planarization layer and electrically connected to the second electrode member of each of the plurality of light emitting diodes, wherein
the first area of the CMOS wafer comprises a plurality of unit areas, on which the plurality of light emitting diodes are disposed, and a boundary area between the plurality of unit areas, and
the planarization layer overlaps the plurality of unit areas and the boundary area.

20. The display device of claim 19, further comprising:
an auxiliary electrode, wherein
a plurality of first trenches overlapping the boundary area and extending in a first direction and a plurality of second trenches overlapping the boundary area and extending in a second direction intersecting the first direction are formed in the planarization layer, and
the auxiliary electrode is disposed inside the plurality of first trenches and the plurality of second trenches and electrically connected to the common electrode.

21. The display device of claim 20, wherein the auxiliary electrode comprises:
a metal member disposed inside the plurality of first trenches and the plurality of second trenches; and
a barrier layer disposed between the metal member and the plurality of first and second trenches.

22. The display device of claim 1, further comprising:
a plurality of dummy light emitting diodes disposed in a second area outside the first area of the CMOS wafer in a plan view,
wherein the plurality of dummy light emitting diodes do not emit light.

23. The display device of claim 22, further comprising:
a common electrode overlapping the first area and the second area and electrically connected to the second electrode member of each of the plurality of light emitting diodes,
wherein the common electrode is not electrically connected to the plurality of dummy light emitting diodes.

24. The display device of claim 22, wherein the plurality of dummy light emitting diodes have a same laminated structure as the plurality of light emitting diodes.

25. The display device of claim 22, further comprising:
a common electrode overlapping the first area and the second area and electrically connected to the second electrode member of each of the plurality of light emitting diodes;
a voltage transmission electrode extending from the common electrode to a third area outside the second area of the CMOS wafer; and
a pad electrode electrically connected to the voltage transmission electrode on the third area.

26. The display device of claim 25, further comprising:
a passivation layer overlapping the first area, the second area, and the third area, covering the common electrode and the voltage transmission electrode, and having an opening through which a connection area of the voltage transmission electrode is exposed,
wherein the pad electrode is electrically connected to the connection area of the voltage transmission electrode through the opening of the passivation layer.

27. The display device of claim 25, further comprising:
a common line disposed below the voltage transmission electrode and electrically connected to the voltage transmission electrode.

28. The display device of claim 27, wherein the common line comprises a first conductive member having a same laminated structure as the first electrode member.

29. The display device of claim 28, wherein the common line comprises:
an insulating member disposed on an upper surface of the first conductive member; and
a second conductive member disposed on at least the first conductive member and electrically connected to the first conductive member.

30. The display device of claim 29, further comprising:
a planarization layer which is disposed between the common line and the voltage transmission electrode and in which a plurality of trenches are formed; and
an auxiliary electrode disposed in the plurality of trenches and electrically connected the common line to the voltage transmission electrode.

31. The display device of claim 30, wherein the auxiliary electrode extends from one area of each of the plurality of trenches and is electrically connected to the common line through through-holes passing through the planarization layer.

32. The display device of claim 30, wherein
the third area of the CMOS wafer comprises an inner area on which the common electrode is disposed and an outer area on which the common electrode is not disposed, and
the auxiliary electrode electrically connects the common electrode to the common line on the inner area.

33. The display device of claim 1, further comprising:
a common electrode electrically connected to the second electrode member of each of the plurality of light emitting diodes to overlap the first area:
a pad electrode disposed on an outer area of the first area to receive a power voltage;
an auxiliary electrode comprising a first portion disposed below the common electrode and electrically connected to the common electrode and a second portion spaced apart from the first portion, disposed below the pad electrode, and electrically connected to the pad electrode; and
a common line comprising a first common portion disposed below the first portion of the auxiliary electrode and electrically connected to the first portion of the auxiliary electrode and a second common portion disposed below the second portion of the auxiliary electrode and electrically connected to the second portion of the auxiliary electrode,
wherein the CMOS wafer comprises a connection electrode electrically connected to each of the first common portion of the common line and the second portion of the common line.

34. The display device of claim 33, wherein
the CMOS wafer comprises:
a silicon substrate in which a source region or a drain region is formed;
a gate electrode disposed on the silicon substrate;
a first insulating layer covering the gate electrode and disposed on the silicon substrate;
a first contact electrode electrically connected to the source region or a drain region through a first contact hole formed in the first insulating layer;
a second insulating layer covering the first contact electrode and disposed on the first insulating layer; and
a second contact electrode electrically connected to the first contact electrode through a second contact hole passing through the second insulating layer and electrically connected to the metal layer of the first electrode member, the connection electrode and the first contact electrode are disposed on a same layer.

35. The display device of claim 1, further comprising:
a plurality of lenses disposed on the plurality of light emitting diodes to respectively correspond to the plurality of light emitting diodes.
